(19) United States
(12) Patent Application Publication
(10) Pub. No.: US 2010/0330425 A1
(43) Pub. Date: Dec. 30, 2010

(54) PASSIVATION FILM FOR SOLID ELECTROLYTE INTERFACE OF THREE DIMENSIONAL COPPER CONTAINING ELECTRODE IN ENERGY STORAGE DEVICE

(75) Inventors: Sergey D. Lopatin, Santa Clara, CA (US); Dmitri A. Brevnov, Santa Clara, CA (US); Ruben Babayants, Mountain View, CA (US); Robert Z. Bachrach, Burlingame, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/826,204

(22) Filed: Jun. 29, 2010

Related U.S. Application Data
(60) Provisional application No. 61/221,342, filed on Jun. 29, 2009.

(51) Int. Cl. H01M 4/485; H01M 4/02; H01M 4/58; H01M 4/136; H01M 4/44; H01M 4/04; B05D 5/12; C23C 14/00; C25B 9/00

(52) U.S. Cl. 429/220; 429/209; 429/231.95; 205/57; 205/66; 205/59; 205/60; 205/61; 427/77; 118/50.1; 204/275.1

(57) ABSTRACT

A system and method for fabricating lithium-ion batteries using thin-film deposition processes that form three-dimensional structures is provided. In one embodiment, an anodic structure used to form an energy storage device is provided. The anodic structure comprises a conductive substrate, a plurality of conductive microstructures formed on the substrate, a passivation film formed over the conductive microstructures, and an insulative separator layer formed over the conductive microstructures, wherein the conductive microstructures comprise columnar projections.

### CROSS-REFERENCE TO RELATED APPLICATIONS

This application claims benefit of U.S. provisional patent application Ser. No. 61/221,342 (Attorney Docket No. 13531L), filed Jun. 29, 2009, which is herein incorporated by reference in its entirety.

### BACKGROUND

1. Field

Embodiments of the present invention relate generally to lithium-ion batteries, and more specifically, to systems and methods for fabricating such batteries using thin-film deposition processes that form three-dimensional structures.

2. Description of the Related Art

Fast-charging, high-capacity energy storage devices, such as supercapacitors and lithium-ion (Li⁺) batteries, are used in a growing number of applications, including portable electronics, medical, transportation, grid-connected large energy storage, renewable energy storage, and uninterruptible power supply (UPS). In modern rechargeable energy storage devices, the current collector is made of an electric conductor. Examples of materials for the positive current collector (the cathode) include aluminum, stainless steel, and nickel. Examples of materials for the negative current collector (the anode) include copper (Cu), stainless steel, and nickel (Ni). Such collectors can be in the form of a foil, a film, or a thin plate, having a thickness that generally ranges from about 6 to 50 μm.

The active electrode material in the positive electrode of a Li-ion battery is typically selected from lithium transition metal oxides, such as LiMn₂O₄, LiCoO₂ and/or LiNiO₂, and includes electroconductive particles, such as carbon or graphite, and binder material. Such positive electrode material is considered to be a lithium-intercalation compound, in which the quantity of conductive material is in the range from 0.1% to 15% by weight.

Graphite is usually used as the active electrode material of the negative electrode and can be in the form of a lithium-intercalation meso-carbon micro beads (MCMB) powder made up of MCMBs having a diameter of approximately 10 μm. The lithium-intercalation MCMB powder is dispersed in a polymeric binder matrix. The polymers for the binder matrix are made of thermoplastic polymers including polymers with rubber elasticity. The polymeric binder serves to bind together the MCMB material powders to preclude crack formation and prevent disintegration of the MCMB powder on the surface of the current collector. The quantity of polymeric binder is in the range of 2% to 30% by weight.

The separator of Li-ion batteries is typically made from micro-porous polyethylene and polyolefin, and is applied in a separate manufacturing step.

For most energy storage applications, the charge time and capacity of energy storage devices are important parameters. In addition, the size, weight, and/or expense of such energy storage devices can be significant limitations.

Accordingly, there is a need in the art for faster charging, higher capacity energy storage devices that are smaller, lighter, and can be more cost effectively manufactured.

### SUMMARY

Embodiments of the present invention relate generally to lithium-ion batteries, and more specifically, to systems and methods for fabricating such batteries using thin-film deposition processes that form three-dimensional structures. In one embodiment, an anodic structure used to form an energy storage device is provided. The anodic structure comprises a conductive substrate, a plurality of conductive microstructures formed on the substrate, a passivation film formed over the conductive microstructures, and an insulative separator layer formed over the conductive microstructures, wherein the conductive microstructures comprise columnar projections.

In another embodiment, a method for forming an anodic structure is provided. The method comprises depositing a plurality of conductive microstructures on a conductive substrate and forming a passivation film over the conductive microstructures.

In yet another embodiment a substrate processing system for processing a flexible substrate is provided. The processing system comprises a first plating chamber configured to plate a conductive microstructure comprising a first conductive material over a portion of the flexible substrate, a first rinse chamber disposed adjacent to the first plating chamber configured to rinse and remove any residual plating solution from the portion of the flexible substrate with a rinsing fluid, a second plating chamber disposed adjacent to the first rinse chamber configured to deposit a second conductive material over the conductive microstructures, a second rinse chamber disposed adjacent to the second plating chamber configured to rinse and remove any residual plating solution from the portion of the flexible substrate, a surface modification chamber configured to form a passivation film on the portion of the flexible substrate, a substrate transfer mechanism configured to transfer the flexible substrate among the chambers, comprising a feed roll configured to retain a portion of the flexible substrate and a take up roll configured to retain a portion of the flexible substrate, wherein the substrate transfer mechanism is configured to activate the feed rolls and the take up rolls to move the flexible substrate in and out of each chamber, and hold the flexible substrate in a processing volume of each chamber.

In yet another embodiment, a method of fabricating a battery cell is provided. The method comprises forming conductive microstructures on a conductive surface of a substrate, forming a passivation film over the conductive microstructures, depositing a fluid permeable, electrically insulative separator layer over the passivation film, depositing an active cathodic material on the electrically insulative separator layer, depositing a current collector on the active cathodic material using a thin film metal deposition process, and depositing a dielectric layer on the current collector, wherein the conductive microstructures comprise columnar projections formed by an electroplating process.

In yet another embodiment, a method of fabricating a battery cell is provided. The method comprises forming an anodic structure by a first thin-film deposition process comprising forming conductive microstructures on a conductive surface of a first substrate, depositing a passivation film over the conductive microstructures, depositing a fluid permeable, electrically insulative separator layer over the passivation film, and depositing an active cathodic material on the electrically insulative separator layer, forming a cathodic structure by a second thin-film deposition process comprising forming conductive microstructures on a conductive surface of a substrate, depositing an active cathodic material on the conductive microstructures, and joining the anodic structure and the cathodic structure together.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a Li-ion battery electrically coupled with a load according to an embodiment described herein;

FIGS. 2A-2G are schematic cross-sectional views of an anodic structure formed according to embodiments described herein;

FIG. 3 schematically illustrates a processing system according to embodiments described herein;

FIG. 4 is a process flow chart summarizing a method for forming an anode structure according to embodiments described herein;

FIG. 5 is a process flow chart summarizing a method for forming an anode structure according to embodiments described herein;

FIG. 6 is a process flow chart summarizing a method for forming an anode structure according to embodiments described herein; and

FIG. 7 is a plot demonstrating the effect of a passivation film formed according to embodiments described herein on storage capacity for energy storage devices.

### DETAILED DESCRIPTION

While the particular apparatus in which the embodiments described herein can be practiced is not limited, it is particularly beneficial to practice the embodiments on a web-based roll-to-roll system sold by Applied Materials, Inc., Santa Clara, Calif. Exemplary roll-to-roll and discrete substrate systems on which the embodiments described herein may be practiced are described herein and in further detail in commonly assigned U.S. Provisional Patent Application Ser. No. 61/243,813, (Attorney Docket No. APPM/014044/ATG/ATG/ESONG), titled APPARATUS AND METHODS FOR FORMING ENERGY STORAGE OR PV DEVICES IN A LINEAR SYSTEM and commonly assigned U.S. patent application Ser. No. 12/620,788, titled APPARATUS AND METHOD FOR FORMING 3D NANOSTRUCTURE ELECTRODE FOR ELECTROCHEMICAL BATTERY AND CAPACITOR, to Lopatin at al., filed Nov. 18, 2009, now published as US2010-0126849, both of which are hereby incorporated by reference in their entirety. Other processing chambers and systems, including those available from other manufactures may also be used to practice the embodiments described herein. One exemplary processing system includes a roll-to-roll processing system described herein.

Embodiments described herein contemplate forming an electrochemical device such as a battery or supercapacitor, using thin-film deposition processes and other methods of forming the same. The embodiments described herein include the formation of a passivation film on a conductive three-dimensional anodic structure. The passivation film may be formed by an electrochemical plating process, an electroless process, a chemical vapor deposition process, a physical vapor deposition process, and combinations thereof. The passivation film assists in the formation and maintenance of a solid electrolyte interface (SEI) and provides high capacity and long cycle life for the electrode. In one embodiment, a porous dielectric separator layer is then formed over the passivation film and the conductive three-dimensional anodic structure to form a half-cell of an energy storage device, such as an anodic structure for a Li-ion battery, or half of a supercapacitor. In one embodiment, the second half-cell of a battery or half of a supercapacitor is formed separately and subsequently joined to the separator layer. In another embodiment, the second half cell or a battery of half of a super capacitor is formed by depositing additional thin films onto the separator layer.

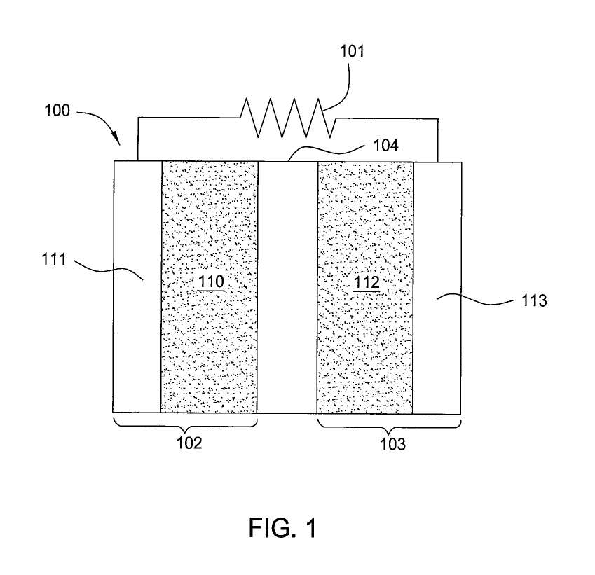

FIG. 1 is a schematic diagram of a Li-ion battery 100 electrically connected to a load 101, according to an embodiment described herein. It should also be understood that although a single layer Li-ion battery cell is depicted in FIG. 1, the embodiments described herein are not limited to single layer Li-ion battery cell structures, for example, the embodiments described herein are also applicable to multi-layer Li-ion battery cells such as bi-layer Li-ion battery cells. The primary functional components of Li-ion battery 100 include an anode structure 102, a cathode structure 103, a separator layer 104, and an electrolyte (not shown) disposed within the region between the opposing current collectors 111 and 113. A variety of materials may be used as the electrolyte, such as a lithium salt in an organic solvent. Lithium salts may include, for example, LiPF₆, LiBF₄, or LiClO₄, and organic solvents may include, for example, ether and ethylene oxide. The electrolyte conducts Lithium ions, acting as a carrier between the anode structure 102 and the cathode structure 103 when a battery passes an electric current through an external circuit. The electrolyte is contained in anode structure 102, cathode structure 103, and a fluid-permeable separator layer 104 in the region formed between the current collectors 111 and 113.

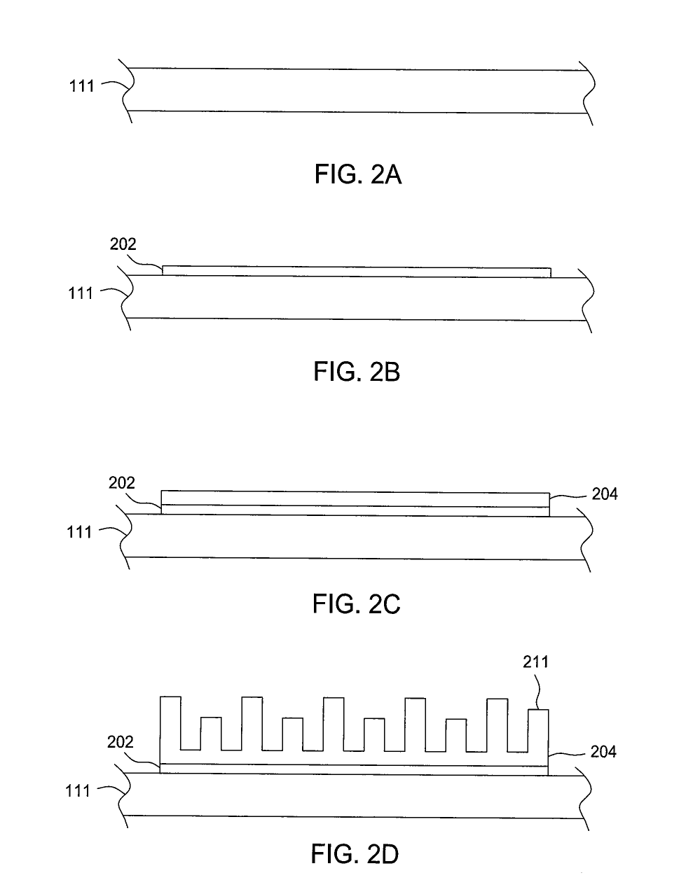

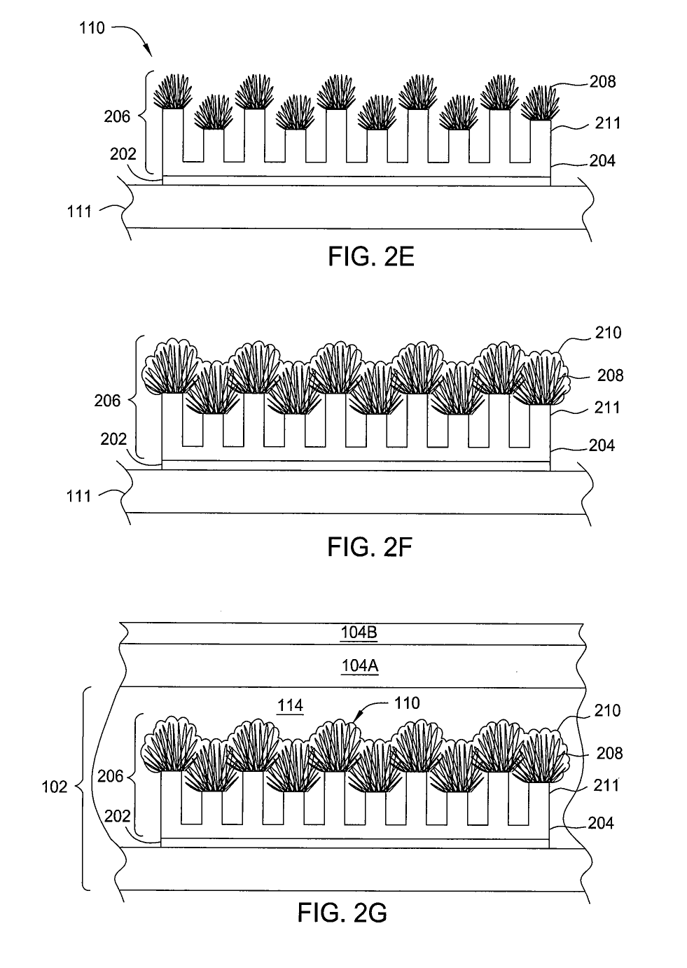

Anode structure 102 and cathode structure 103 each serve as a half-cell of Li-ion battery 100, and together form a complete working cell of Li-ion battery 100. Both the anode structure 102 and the cathode structure 103 comprise material into which and from which lithium ions can migrate. Anode structure 102 includes a current collector 111 and a conductive microstructure 110 that acts as an intercalation host material for retaining lithium ions. Similarly, cathode structure 103 includes a current collector 113 and an intercalation host material 112 for retaining lithium ions, such as a metal oxide. Separator layer 104 is a dielectric, porous, fluid-permeable layer that prevents direct electrical contact between the components in the anode structure 102 and the cathode structure 103. Methods of forming Li-ion battery 100, as well as the materials that make up the constituent parts of Li-ion battery 100, i.e., anode structure 102, cathode structure 103, and separator layer 104, are described below in conjunction with FIGS. 2A-G.

Rather than the traditional redox galvanic action of a conventional secondary cell, Li-ion secondary cell chemistry depends on a fully reversible intercalation mechanism, in which lithium ions are inserted into the crystalline lattice of an intercalation host material in each electrode without changing the crystal structure of the intercalation host material. Thus, it is necessary for such intercalation host materials in the electrodes of a Li-ion battery to have open crystal structures that allow the insertion or extraction of lithium ions and have the ability to accept compensating electrons at the same time. In Li-ion battery 100, the anode, or negative electrode, is based on a conductive microstructure 110. The conductive microstructure may be a metal selected from a group comprising copper, zinc, nickel, cobalt, palladium, platinum, tin, ruthenium, alloys thereof, and combinations thereof.

The cathode structure 103, or positive electrode, is made from a metal oxide, such as lithium cobalt dioxide (LiCoO₂) or lithium manganese dioxide (LiMnO₂). The cathode structure 103 may be made from a layered oxide, such as lithium cobalt oxide, a polyanion, such as lithium iron phosphate, a spinel, such as lithium manganese oxide, or TiS₂ (titanium disulfide). Exemplary oxides may be layered lithium cobalt oxide, or mixed metal oxide, such as LiNi_{X}CO₁₋₂ₓ, MnO₂, LiMn₂O₄. Exemplary phosphates may be iron olivine (LiFePO₄) and it is variants (such as LiFe_{1-X}MgPO₄), LiMoPO₄, LiCoPO₄, Li₃V₂(PO₄)₃, LiVOPO₄, LiMP₂O₇, or LiFe_{1.5}P₂O₇. Exemplary fluorophosphates may be LiVPO₄F, LiAlPO₄F, Li₅V(PO₄)₂F₂, Li₅Cr(PO₄)₂F₂, Li₂CoPO₄F, Li₂NiPO₄F, or Na₅V₂(PO₄)₂F₃. Exemplary silicates may be Li₂FeSiO₄, Li₂MnSiO₄, or Li₂VOSiO₄.

Separator layer 104 is configured to supply ion channels for movement between the anode structure 102 and the cathode structure 103 while keeping the anode structure 102 physically separated from the cathode structure 103 to avoid a short. In one embodiment, the separator layer 104 may be formed as an upper layer of the conductive microstructure 110. Alternatively, separator layer 104 deposited onto the surface of the conductive microstructure 110 and may be a solid polymer, such as polyolefin, polypropylene, polyethylene, and combinations thereof.

In operation, the Li-ion battery 100 provides electrical energy, i.e., energy is discharged, when the anode structure 102 and the cathode structure 103 are electrically coupled to the load 101, as shown in FIG. 1. Electrons originating from the conductive microstructure 110 flow from the current collector 111 of the anode structure 102 through the load 101 and the current collector 113 to the intercalation host material 112 of the cathode structure 103. Concurrently, lithium ions are dissociated, or extracted, from the conductive microstructure 110 of the anode structure 102, and move through the separator layer 104 into the intercalation host material 112 of the cathode structure 103 and are inserted into the crystal structure of the intercalation host material 112. The electrolyte, which resides in the conductive microstructure 110, the intercalation host material 112, and the separator layer 104, allows the movement of lithium ions from the conductive microstructure 110 to the intercalation host material 112 via ionic conduction. The Li-ion battery 100 is charged by electrically coupling an electromotive force of an appropriate polarity to the anode structure 102 and the cathode structure 103 in lieu of the load 101. Electrons then flow from the current collector 113 of the cathode structure 103 to the current collector 111 of the anode structure 102, and lithium ions move from the intercalation host material 112 in the cathode structure 103, through the separator layer 104, and into the conductive microstructure 110 of the anode structure 102. Thus, lithium ions are intercalated into the cathode structure 103 when the Li-ion battery 100 is discharged and into the anode structure 102 when the Li-ion battery 100 is in the charged state.

When a great enough potential is established on the anode structure 102 and appropriate organic solvents are used as the electrolyte, the solvent is decomposed and forms a solid layer called the solid electrolyte interphase (SEI) at first charge that is electrically insulating yet sufficiently conductive to lithium ions. The SEI prevents decomposition of the electrolyte after the second charge. The SEI can be thought of as a three layer system with two important interfaces. In conventional electrochemical studies, it is often referred to as an electrical double layer. In its simplest form, an anode coated by an SEI will undergo three steps when charged: electron transfer between the anode (M) and the SEI (M⁰-ne→Mⁿ⁺M/SEI); cation migration from the anode-SEI interface to the SEI-electrolyte (E) interface (Mⁿ⁺M/SEI→Mⁿ⁺SEI/E); and cation transfer in the SEI to electrolyte at the SEI/electrolyte interface (E(so/v)+Mⁿ⁺SEI/E→Mⁿ⁺E(solv)).

The power density and recharge speed of the battery is dependent on how quickly the anode can release and gain charge. This, in turn, is dependent on how quickly the anode can exchange Li⁺ with the electrolyte through the SEI. Li⁺ exchange at the SEI is a multi-step process as previously described, and as with most multi-step processes, the speed of the entire process is dependent upon the slowest step. Studies have shown that cation migration is the bottleneck for most systems. It was also found that the diffusive characteristics of the solvents dictate the speed of migration between the anode-SEI interface and the SEI-electrolyte (E) interface. Thus, the best solvents have little mass in order to maximize the speed of diffusion.

Although the specific properties and reactions that take place at the SEI are not well understood, it is known that these properties and reactions can have profound effects on the cyclability and capacity of the anode structure. It is believed that when cycled, the SEI can thicken, making diffusion from the Electrode/SEI interface to the SEI/Electrolyte interface longer. This, in turn, causes the battery to have much lower power density. Furthermore, the thickening of the SEI can damage the fragile microstructures of the high surface area of the microstructures of the nano-materials.

FIGS. 2A-2G are schematic cross-sectional views of an anode structure formed according to embodiments described herein. In FIG. 2A, current collector 111 is schematically illustrated prior to the formation of the conductive microstructures 206 and passivation layer or film 210. Current collector 111 may include a relatively thin conductive layer disposed on a substrate or simply a conductive substrate (e.g., foil, sheet, or plate), comprising one or more materials, such as metal, plastic, graphite, polymers, carbon containing polymers, composites or other suitable materials. Examples of metals that current collector 111 may be comprised of include copper (Cu), zinc (Zn), nickel (Ni), cobalt (Co), palladium (Pd), platinum (Pt), tin (Sn), ruthenium (Ru), stainless steel, alloys thereof, and combinations thereof. In one embodiment, current collector 111 is a metallic foil and may have an insulating coating disposed thereon. Alternatively, current collector 111 may comprise a host substrate that is non-conductive, such as a glass, silicon, plastic or a polymeric substrate that has an electrically conductive layer formed thereon by means known in the art, including physical vapor deposition (PVD), electrochemical plating, electroless plating, and the like. In one embodiment, the current collector 111 is formed out of a flexible host substrate. The flexible host substrate may be a lightweight and inexpensive plastic material, such as polyethylene, polypropylene or other suitable plastic or polymeric material, with a conductive layer formed thereon. Materials suitable for use as such a flexible substrate include a polyimide (e.g., KAPTON™ by DuPont Corporation), polyethyleneterephthalate (PET), polyacrylates, polycarbonate, silicone, epoxy resins, silicone-functionalized epoxy resins, polyester (e.g., MYLAR™ by E.I. du Pont de Nemours & Co.), APICAL AV manufactured by Kanegaftigi Chemical Industry Company, UPILEX manufactured by UBE Industries, Ltd.; polyethersulfones (PES) manufactured by Sumitomo, a polyetherimide (e.g., ULTEM by General Electric Company), and polyethylenenaphthalene (PEN). Alternately, the flexible substrate may be constructed from a relatively thin glass that is reinforced with a polymeric coating.

As shown in FIG. 2B, an optional barrier layer 202 or adhesion layer may be deposited over the current collector 111. The barrier layer 202 may be used to prevent or inhibit diffusion of subsequently deposited materials over the barrier layer into the underlying substrate. In one embodiment the barrier layer comprises multiple layers such as a barrier-adhesion layer or an adhesion-release layer. Examples of barrier layer materials include refractory metals and refractory metal nitrides such as chromium, tantalum (Ta), tantalum nitride (TaNₓ), titanium (Ti), titanium nitride (TiNₓ), tungsten (W), tungsten nitride (WNₓ), alloys thereof, and combinations thereof. Other examples of barrier layer materials include PVD titanium stuffed with nitrogen, doped silicon, aluminum, aluminum oxides, titanium silicon nitride, tungsten silicon nitride, and combinations thereof. Exemplary barrier layers and barrier layer deposition techniques are further described in commonly assigned U.S. Patent Application Publication 2003/0143837 entitled “Method of Depositing A Catalytic Seed Layer,” filed on Jan. 28, 2002, which is incorporated herein by reference to the extent not inconsistent with the embodiments described herein. The barrier layer may be deposited by CVD techniques, PVD techniques, electroless deposition techniques, evaporation, or molecular beam epitaxy.

As shown in FIG. 2C, to aid in the deposition of columnar projections 211 a conductive seed layer 204 may optionally be deposited over the current collector 111. The conductive seed layer 204 comprises a conductive metal that aids in subsequent deposition of materials thereover. The conductive seed layer 204 may comprise a copper seed layer or alloys thereof. Other metals, particularly noble metals, may also be used for the seed layer. The conductive seed layer 204 may be deposited over the barrier layer by techniques conventionally known in the art including physical vapor deposition techniques, chemical vapor deposition techniques, and electroless deposition techniques. Alternatively, columnar projections 211 may be formed by an electrochemical plating process directly on the current collector 111, i.e., without the conductive seed layer 204.

As shown in FIGS. 2D and 2E, the conductive microstructures 206 including the columnar projections 211 and dendritic structures 208 are formed over the seed layer 204. Formation of the conductive microstructures 206 includes establishing process conditions under which evolution of hydrogen results in the formation of a porous metal film. In one embodiment, such process conditions are achieved by performing at least one of: increasing the concentration of metal ions near the cathode (e.g., seed layer surface) by reducing the diffusion boundary layer, and by increasing the metal ion concentration in the electrolyte bath. It should be noted that the diffusion boundary layer is strongly related to the hydrodynamic boundary layer. If the metal ion concentration is too low and/or the diffusion boundary layer is too large at a desired plating rate the limiting current (i_{L}) will be reached. The diffusion limited plating process created when the limiting current is reached, prevents the increase in plating rate by the application of more power (e.g., voltage) to the cathode (e.g., metalized substrate surface). When the limiting current is reached low density columnar projections 211 are produced due to the evolution of gas and resulting dendritic type film growth that occurs due to the mass transport limited process.

Although discussed as a plating process, it should also be understood that the columnar projections may be formed using other processes, for example, an embossing process.

Next, three-dimensional porous metallic structures or dendritic structures 208 may be formed on the columnar projections 211 as shown in FIG. 2E. The dendritic structures 208 may be formed on the columnar projections 211 by increasing the voltage and corresponding current density from the deposition of the columnar microstructures 206. In one embodiment, the dendritic structures are formed by an electrochemical plating process in which the over potential, or applied voltage used to form the dendritic structures 208 is significantly greater than that used to form the columnar projections 211, thereby producing a three dimensional low-density metallic dendritic structure 208 on the columnar projections 211. In one embodiment, the dendritic structures 208 are formed using an electroless process. In one embodiment, the deposition bias generally has a current density of about 10 A/cm² or less. In another embodiment, the deposition bias generally has a current density of about 5 A/cm² or less. In yet another embodiment, the deposition bias has a current density of about 3 A/cm² or less. In one embodiment, the deposition bias has a current density in the range from about 0.3 A/cm² to about 3.0 A/cm². In another embodiment, the deposition bias has a current density in the range of about 1 A/cm² and about 2 A/cm². In yet another embodiment, the deposition bias has a current density in the range of about 0.5 A/cm² and about 2 A/cm². In yet another embodiment, the deposition bias has a current density in the range of about 0.3 A/cm² and about 1 A/cm². In yet another embodiment, the deposition bias has a current density in the range of about 0.3 A/cm² and about 2 A/cm². In one embodiment, the dendritic structures 208 have a porosity of between 30% and 70%, for example, about 50%, of the total surface area.

In one embodiment, the conductive microstructures 206 may comprise one or more of various forms of porosities. In one embodiment, the conductive microstructures 206 comprise a macro-porous structure having macro-pores of about 100 microns or less in diameter. In one embodiment, the macro-pores 213A are sized within a range between about 5 and about 100 microns (μm). In another embodiment, the average size of the macro-pores is about 30 microns in size. The conductive microstructures 206 may also comprise a second type, or class, of pore structures that are formed between the columnar projections 211 and/or main central bodies of the dendrites 208, which is known as a meso-porous structure. The meso-porous structure may have a plurality of meso-pores that are less than about 1 micron in size or diameter. In another embodiment, the meso-porous structure may have a plurality of meso-pores 213B that are between about 100 nm to about 1,000 nm in size or diameter. In one embodiment, the meso-pores are between about 2 nm to about 50 nm in diameter. Additionally, the conductive microstructures 206 may also comprise a third type, or class, of pore structures that are formed between the dendrites, which is known as a nano-porous structure. In one embodiment, the nano-porous structure may have a plurality of nano-pores that are sized less than about 100 nm in diameter. In another embodiment, the nano-porous structure may have a plurality of nano-pores that are less than about 20 nm in size or diameter. The combination of micro-porous, meso-porous, and nano-porous structures yields a significant increase in the surface area of the conductive microstructures 206.

In one embodiment, the dendritic structures 208 may be formed from a single material, such as copper, zinc, nickel, cobalt, palladium, platinum, tin, ruthenium, and other suitable materials. In another embodiment, the dendritic structures 208 may comprise alloys of copper, zinc, nickel, cobalt, palladium, platinum, tin, ruthenium, combinations thereof, alloys thereof, or other suitable materials.

As shown in FIG. 2F, a passivation film 210 is formed over the conductive microstructures 206. The passivation film 210 can be formed by a process selected from the group comprising an electrochemical plating process (ECP), a chemical vapor deposition process (CVD), a physical vapor deposition process (PVD), an electroless process, and combinations thereof. It is believed that the passivation film 210 assists in the formation of the solid electrolyte interface (SEI) and provides high capacity and long cycle life for the electrode to be formed. In one embodiment, the passivation film 210 has a thickness between about 1 nm and about 1,000 nm. In another embodiment, the passivation film 210 has a thickness between about 200 nm and about 800 nm. In yet another embodiment, the passivation film 210 has a thickness between about 400 nm and about 600 nm.

In one embodiment, the passivation film 210 is a copper containing film selected from the group comprising copper oxides (Cu₂O, CuO, Cu₂O—CuO), copper-chlorides (CuCl), copper-sulfides (Cu₂S, CuS, Cu₂S—CuS), copper-nitriles, copper-carbonates, copper-phosphides, copper-tin oxides, copper-cobalt-tin oxides, copper-cobalt-tin-titanium oxides, copper-silicon oxides, copper-nickel oxides, copper-cobalt oxides, copper-cobalt-tin-titanium oxides, copper-cobalt-nickel-aluminum oxides, copper-titanium oxides, copper-manganese oxides, and copper-iron phosphates. In one embodiment, the passivation film 210 is an aluminum containing film such as an aluminum-silicon film. In one embodiment, the passivation film 210 is a lithium containing film selected from the group comprising lithium-copper-phosphorous-oxynitride (P—O—N), lithium-copper-boron-oxynitride (B—O—N), lithium-copper-oxides, lithium-copper-silicon oxides, lithium-copper-nickel oxides, lithium-copper-tin oxides, lithium-copper-cobalt oxides, lithium-copper-cobalt-tin-titanium oxides, lithium-copper-cobalt-nickel-aluminum oxides, lithium-copper-titanium oxides, lithium-aluminum-silicon, lithium-copper-manganese oxides, and lithium-copper-iron-phosphides. In one embodiment, lithium is inserted into the lithium containing films after the first charge.

In another embodiment, the lithium containing film is “pre-lithiated” where lithium is inserted into the passivation film by exposing the passivation film to a lithium containing solution. In one embodiment, the pre-lithiation process may be performed by adding a lithium source to the aforementioned plating solutions. Suitable lithium sources include but are not limited to LiH₂PO₄, LiOH, LiNO₃, LiCH₃COO, LiCl, Li₂SO₄, Li₃PO₄, Li(C₅H₈O₂), Li₂CO₃, lithium surface stabilized particles (e.g. carbon coated lithium particles), and combinations thereof. The pre-lithiation process may further comprise adding a complexing agent, for example, citric acid and salts thereof to the plating solution. In one embodiment, the pre-lithiation process results in an electrode comprising about 1-40 atomic percent lithium. In another embodiment, the pre-lithiation process results in an electrode comprising about 10-25 atomic percent lithium.

In certain embodiments, the pre-lithiation process may be performed by applying lithium to the electrode in a particle form using powder application techniques including but not limited to sifting techniques, electrostatic spraying techniques, thermal or flame spraying techniques, fluidized bed coating techniques, slit coating techniques, roll coating techniques, and combinations thereof, all of which are known to those skilled in the art. In one embodiment, lithium is deposited using a plasma spraying process. In one embodiment, the passivation film 210 may be formed by immersing the substrate in a new plating bath for plating the passivation film 210.

In one embodiment, a rinsing step is performed prior to immersing the substrate in the new plating bath. In one embodiment, the passivation film 210 is exposed to a post deposition anneal process.

In one embodiment, the passivation layer is formed by an electroplating process in a processing chamber that may be adapted to perform one or more of the process steps described herein, such as the SLIMCELL® electroplating chamber available from Applied Materials, Inc. of Santa Clara, Calif.

The processing chamber includes a suitable plating solution. Suitable plating solutions that may be used with the processes described herein include electrolyte solutions containing a metal ion source, an acid solution, and optional additives.

### Plating Solutions:

In one embodiment the plating solution contains a metal ion source and at least one or more acid solutions. Suitable acid solutions include, for example, inorganic acids such as sulfuric acid, phosphoric acid, pyrophosphoric acid, perchloric acid, acetic acid, citric acid, combinations thereof, as well as acid electrolyte derivatives, including ammonium and potassium salts thereof.

In one embodiment, the metal ion source within the plating solution used to form the passivation film 210 is a copper ion source. Useful copper sources include copper sulfate (CuSO₄), copper (I) sulfide (Cu₂S), copper (II) sulfide (CuS), copper (I) chloride (CuCl), copper (II) chloride (CuCl₂), copper acetate (Cu(CO₂CH₃)₂), copper pyrophosphate (Cu₂P₂O₇), copper fluoroborate (Cu(BF₄)₂), copper acetate ((CH₃CO₂)₂Cu), copper acetylacetonate ((C₅H₇O₂)₂Cu), copper phosphates, copper nitrates, copper carbonates, copper sulfamate, copper sulfonate, copper pyrophosphate, copper cyanide, derivatives thereof, hydrates thereof or combinations thereof. Some copper sources are commonly available as hydrate derivatives, such as CuSO₄5H₂O, CuCl₂2H₂O and (CH₃CO₂)₂CuH₂O. The electrolyte composition can also be based on the alkaline copper plating baths (e.g., cyanide, glycerin, ammonia, etc) as well. In one embodiment, the concentration of copper ions in the electrolyte may range from about 0.1 M to about 1.1M. In one embodiment, the concentration of copper ions in the electrolyte may range from about 0.4 M to about 0.9 M.

Optionally, the plating solution may include one or more additive compounds. In certain embodiments, the plating solution contains an oxidizer. As used herein, an oxidizer may be used to oxidize a metal layer to a corresponding oxide, for example, copper to copper oxide. Examples of suitable oxidizers include peroxy compounds, e.g., compounds that may disassociate through hydroxy radicals, such as hydrogen peroxide and its adducts including urea hydrogen peroxide, percarbonates, and organic peroxides including, for example, alkyl peroxides, cyclical or aryl peroxides, benzoyl peroxide, peracetic acid, and di-t-butyl peroxide. Sulfates and sulfate derivatives, such as monopersulfates and dipersulfates may also be used including for example, ammonium peroxydisulfate, potassium peroxydisulfate, ammonium persulfate, and potassium persulfate. Salts of peroxy compounds, such as sodium percarbonate and sodium peroxide may also be used. In one embodiment, the oxidizer can be present in the plating solution in an amount ranging between about 0.001% and about 90% by volume or weight. In another embodiment, the oxidizer can be present in the plating solution in an amount ranging between about 0.01% and about 20% by volume or weight. In yet another embodiment, the oxidizer can be present in the plating solution in an amount ranging between about 0.1% and about 15% by volume or weight.

In certain embodiments, it is desirable to add a low cost pH adjusting agent, such as potassium hydroxide (KOH) or sodium hydroxide (NaOH) to form an inexpensive electrolyte that has a desirable pH to reduce the cost of ownership required to form an energy device. In some cases it is desirable to use tetramethylammonium hydroxide (TMAH) to adjust the pH.

In one embodiment, it may be desirable to add a second metal ion to the primary metal ion containing electrolyte bath (e.g., copper ion containing bath) that will plate out or be incorporated in the growing electrochemically deposited layer or on the grain boundaries of the electrochemically deposited layer. The formation of a metal layer that contains a percentage of a second element can be useful to reduce the intrinsic stress of the formed layer and/or improve its electrical and electromigration properties. In one example, the metal ion source within the electrolyte solution is an ion source selected from a group comprising silver, tin, zinc, cobalt, nickel ion sources, and combinations thereof. In one embodiment, the concentration of silver (Ag), tin (Sn), zinc (Zn), cobalt (Co), or nickel (Ni) ions in the electrolyte may range from about 0.1 M to about 0.4M.

Examples of suitable nickel sources include nickel sulfate, nickel chloride, nickel acetate, nickel phosphate, derivatives thereof, hydrates thereof or combinations thereof.

Examples of suitable tin sources include soluble tin compounds. A soluble tin compound can be a stannic or stannous salt. The stannic or stannous salt can be a sulfate, an alkane sulfonate, or an alkanol sulfonate. For example, the bath soluble tin compound can be one or more stannous alkane sulfonates of the formula:

(RSO₃)₂Sn

where R is an alkyl group that includes from one to twelve carbon atoms. The stannous alkane sulfonate can be stannous methane sulfonate with the formula:

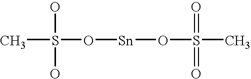

and the bath soluble tin compound can also be stannous sulfate of the formula:

SnSO₄.

Examples of the soluble tin compound can also include tin(II) salts of organic sulfonic acid such as methanesulfonic acid, ethanesulfonic acid, 2-propanolsulfonic acid, p-phenolsulfonic acid and like, tin(II) borofluoride, tin(II) sulfosuccinate, tin(II) sulfate, tin(II) oxide, tin(II) chloride and the like. These soluble tin(II) compounds may be used alone or in combination of two or more kinds.

Example of suitable cobalt sources may include cobalt salts selected from cobalt sulfate, cobalt nitrate, cobalt chloride, cobalt bromide, cobalt carbonate, cobalt acetate, ethylene diamine tetraacetic acid cobalt, cobalt (II) acetyl acetonate, cobalt (III) acetyl acetonate, glycine cobalt (III), cobalt pyrophosphate, and combinations thereof.

The plating solution may also contain manganese or iron at a concentration within a range from about 20 ppb to about 600 ppm. In another embodiment, the plating solution may contain manganese or iron at a concentration within a range from about 100 ppm to about 400 ppm. Possible iron sources include iron(II) chloride (FeCl₂) including hydrates, iron (III) chloride (FeCl₃), iron (II) oxide (FeO), Iron (II, III) oxide (Fe₃O₄), and Iron (III) oxide (Fe₂O₃). Possible manganese sources include manganese (IV) oxide (MnO₂), manganese (II) sulfate monohydrate (MnSO₄.H₂O), manganese (II) chloride (MnCl₂), manganese (III) chloride (MnCl₃), manganese fluoride (MnF₄), and manganese phosphate (Mn₃(PO₄)₂).

In one embodiment, the plating solution contains free copper ions in place of copper source compounds and complexed copper ions.

In certain embodiments, the plating solution may also comprise at least one complexing agent or chelator to form complexes with the copper ions while providing stability and control during the deposition process. Complexing agents also provide buffering characteristics for the electroless copper solution. Complexing agents generally have functional groups, such as carboxylic acids, dicarboxylic acids, polycarboxylic acids, amino acids, amines, diamines or polyamines. Specific examples of useful complexing agents for the electroless copper solution include ethylene diamine tetraacetic acid (EDTA), ethylene diamine (EDA), citric acid, citrates, glyoxylates, glycine, amino acids, derivatives thereof, salts thereof or combinations thereof. In one embodiment, the plating solution may have a complexing agent at a concentration within a range from about 50 mM to about 500 mM. In another embodiment, the plating solution may have a complexing agent at a concentration within a range from about 75 mM to about 400 mM. In yet another embodiment, the plating solution may have a complexing agent at a concentration within a range from about 100 mM to about 300 mM, such as about 200 mM. In one embodiment, an EDTA source is the preferred complexing agent within the plating solution. In one example, the plating solution contains about 205 mM of an EDTA source. The EDTA source may include EDTA, ethylenediaminetetraacetate, salts thereof, derivatives thereof or combinations thereof.

In certain embodiments, the plating solution contains at least one reductant. Reductants provide electrons to induce the chemical reduction of copper ions while forming and depositing the copper material, as described herein. Reductants include organic reductants (e.g., glyoxylic acid or formaldehyde), hydrazine, organic hydrazines (e.g., methyl hydrazine), hypophosphite sources (e.g., hypophosphorous acid (H₃PO₂), ammonium hypophosphite ((NH₄)₄₋ₓHₓPO₂) or salts thereof), borane sources (e.g., dimethylamine borane complex ((CH₃)₂NHBH₃), DMAB), trimethylamine borane complex ((CH₃)₃NBH₃), TMAB), tert-butylamine borane complex (tBuNH₂BH₃), tetrahydrofuran borane complex (THFBH₃), pyridine borane complex (C₅H₅NBH₃), ammonia borane complex (NH₃BH₃), borane (BH₃), diborane (B₂H₆), derivatives thereof, complexes thereof, hydrates thereof or combinations thereof. In one embodiment, the plating solution may have a reductant at a concentration within a range from about 20 mM to about 500 mM. In another embodiment, the plating solution may have a reductant at a concentration within a range from about 100 mM to about 400 mM. In yet another embodiment, the plating solution may have a reductant at a concentration within a range from about 150 mM to about 300 mM, such as about 220 mM. Preferably, an organic reductant or organic-containing reductant is utilized within the plating solution, such as glyoxylic acid or a glyoxylic acid source. The glyoxylic acid source may include glyoxylic acid, glyoxylates, salts thereof, complexes thereof, derivatives thereof or combinations thereof. In a preferred example, glyoxylic acid monohydrate (HCOCO₂H.H₂O) is contained within the electroless copper solution at a concentration of about 217 mM.

Other additive compounds include electrolyte additives including, but not limited to, inhibitors, enhancers, levelers, brighteners and stabilizers to improve the effectiveness of the plating solution for depositing metal, namely copper to the substrate surface. Useful suppressors typically include polyethers, such as polyethylene glycol, polypropylene glycol, or other polymers, such as polypropylene oxides, which adsorb on the substrate surface, slowing down copper deposition in the adsorbed areas.

Inhibitors within the plating solution are used for suppressing copper deposition by initially adsorbing onto underlying surfaces (e.g., substrate surface) and therefore blocking access to the surface. A predetermined concentration of an inhibitor or inhibitors within the plating solution may be varied to control the amount of blocked underlying surfaces, and therefore, provides additional control of the copper material deposition.

Specific examples of useful inhibitors for the plating solution include 2,2′-dipyridyl, dimethyl dipyridyl, polyethylene glycol (PEG), polypropylene glycol (PPG), polyoxyethylene-polyoxypropylene copolymer (POCP), benzotriazole (BTA), sodium benzoate, sodium sulfite, derivatives thereof or combinations thereof. In one embodiment, the plating solution may have an inhibitor at a concentration within a range from about 20 ppb to about 600 ppm. In another embodiment, the plating solution may have an inhibitor at a concentration within a range from about 100 ppb to about 200 ppm. In yet another embodiment, the plating solution may have an inhibitor at a concentration within a range from about 10 ppm to about 100 ppm. In one example, the polyoxyethylene-polyoxypropylene copolymer is used as a mixture of polyoxyethylene and polyoxypropylene at different weight ratios, such as 80:20, 50:50 or 20:80. In another example, a PEG-PPG solution may contain a mixture of PEG and PPG at different weight ratios, such as 80:20, 50:50 PATENT or 20:80. In one embodiment, PEG, PPG or 2,2′-dipyridyl may be used alone or in combination as an inhibitor source within the electroless copper solution. In one embodiment, the electroless copper solution contains PEG or PPG at a concentration within a range from about 0.1 g/L to about 1.0 g/L. In another embodiment, the electroless copper solution contains PEG or PPG at a concentration of about 0.5 g/L. In one embodiment, the plating solution contains 2,2′-dipyridyl at a concentration within a range from about 10 ppm to about 100 ppm. In another embodiment, the plating solution contains 2,2′-dipyridyl at a concentration of about 25 ppm. In another embodiment, the plating solution contains PEG or PPG at a concentration within a range from about 0.1 g/L to about 1.0 g/L, for example, about 0.5 g/L and also contains 2,2′-dipyridyl at a concentration within a range from about 10 ppm to about 100 ppm, for example, about 25 ppm.

The plating solution may contain other additives to help accelerate the deposition process. Useful accelerators typically include sulfides or disulfides, such as bis(3-sulfopropyl) disulfide, which compete with suppressors for adsorption sites, accelerating copper deposition in adsorbed areas.

Levelers within the plating solution are used to achieve different deposition thickness as a function of leveler concentration and feature geometry while depositing copper materials. In one embodiment, the plating solution may have a leveler at a concentration within a range from about 20 ppb to about 600 ppm. In another embodiment, the plating solution may have a leveler concentration from about 100 ppb to about 100 ppm. Examples of levelers that may be employed in the plating solution include, but are not limited to, alkylpolyimines and organic sulfonates, such as 1-(2-hydroxyethyl)-2-imidazolidinethione (HIT), 4-mercaptopyridine, 2-mercaptothiazoline, ethylene thiourea, thiourea, thiadiazole, imidazole, and other nitrogen containing organics, organic acid amides and amine compounds, such as acetamide, propyl amide, benz amide, acrylic amide, methacrylic amide, N,N-dimethylacrylic amide, N,N-diethyl methacrylic amide, N,N-diethyl acrylic amide, N,N-dimethyl methacrylic amide, N-(hydroxymethyl)acrylic amide, polyacrylic acid amide, hydrolytic product of poly acrylic acid amide, thioflavine, safranine, and combinations thereof.

A brightener may be contained within the electroless copper solution as an additive to provide further control of the deposition process. The role of a brightener is to achieve a smooth surface of the deposited copper material. In one embodiment, the plating solution may have an additive (e.g., brightener) at a concentration within a range from about 20 ppb to about 600 ppm. In another embodiment, the plating solution may have an additive at a concentration from about 100 ppb to about 100 ppm. Additives that are useful within the plating solution for depositing copper materials may include sulfur-based compounds such as bis(3-sulfopropyl)disulfide (SPS), 3-mercapto-1-propane sulfonic acid (MPSA), aminoethane sulfonic acids, thiourea, derivatives thereof or combinations thereof.

The plating solution may also have a surfactant. The surfactant acts as a wetting agent to reduce the surface tension between the electroless copper solution and the substrate surface. In one embodiment, the plating solution generally contains a surfactant at a concentration of about 1,000 ppm or less. In another embodiment, the plating solution generally contains a surfactant at a concentration of about 500 ppm or less, such as within a range from about 100 ppm to about 300 ppm. The surfactant may have ionic or non-ionic characteristics. A preferred surfactant includes glycol ether based surfactants, such as polyethylene glycol (PEG), polypropylene glycol (PPG) or the like. Due to beneficial characteristics, PEG and PPG may be used as a surfactant, an inhibitor and/or a suppressor. In one example, a glycol ether based surfactant may contain polyoxyethylene units, such as TRITON® 100, available from Dow Chemical Company. Other surfactants that may be used within the electroless copper solution include dodecyl sulfates, such as sodium dodecyl sulfate (SDS). The surfactants may be single compounds or a mixture of compounds having molecules that contain varying lengths of hydrocarbon chains.

The balance or remainder of the plating solution described above may be a solvent, such as a polar solvent, including water, such as deionized water, and organic solvents, for example, alcohols or glycols.

### Silicon Deposition:

In certain embodiments, where the passivation film 210 comprises silicon, the silicon may be deposited using chemical vapor deposition or plasma enhanced chemical vapor deposition techniques. In one embodiment, the silicon source is provided into a process chamber at a rate in a range from about 5 sccm to about 500 sccm. In another embodiment, the silicon source is provided into a process chamber at a rate in a range from about 10 sccm to about 300 sccm. In yet another embodiment, the silicon source is provided into a process chamber at a rate in a range from about 50 sccm to about 200 sccm, for example, about 100 sccm. Silicon sources useful in the deposition gas to deposit silicon-containing compounds include silanes, halogenated silanes and organosilanes. Silanes include silane (SiH₄) and higher silanes with the empirical formula SiₓH₍₂ₓ₊₂₎, such as disilane (Si₂H₆), trisilane (Si₃H₈), and tetrasilane (Si₄H₁₀), as well as others. Halogenated silanes include compounds with the empirical formula X′_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂). Organosilane compounds have been found to be advantageous silicon sources as well as carbon sources in embodiments which incorporate carbon in the deposited silicon-containing compound.

### Aluminum Deposition:

In certain embodiments, where the passivation film 210 comprises aluminum, the aluminum may be deposited using known PVD techniques.

FIG. 2G illustrates the anode structure 102 after formation a separator layer 104 on an optional carbon containing material 114. In one embodiment, the carbon containing material 114 comprises a mesoporous carbon material 114. In one embodiment, the mesoporous carbon containing material 114 is comprised of CVD-deposited carbon fullerene onions connected by carbon nano-tubes (CNTs) in a three-dimensional, high-surface-area lattice that are deposited over the passivation film 210. The mesoporous carbon containing material is further described in commonly assigned U.S. patent application Ser. No. 12/459,313 titled THIN FILM ELECTROCHEMICAL ENERGY STORAGE DEVICE WITH THREE-DIMENSIONAL ANODIC STRUCTURE, filed Jun. 30, 2009, which is hereby incorporated by reference in its entirety. In one embodiment, the carbon containing material may be pre-lithiated. In one embodiment, lithium is inserted into the active carbon containing material by exposing the passivation film to a lithium containing solution or particles, for example, lithium hydroxide (LiOH), lithium chloride (LiCl), lithium sulfate (Li₂SO₄), lithium carbonate (Li₂CO₃), LiH₂PO₄, lithium nitrate (LiNO₃), LiCH₃COO, lithium phosphate (Li₃PO₄), Li(C₅H₈O₂), lithium surface stabilized particles (e.g. carbon coated lithium particles), or combinations thereof.

Polymerized carbon layer 104A comprises a densified layer of mesoporous carbon material 114 on which dielectric layer 104B may be deposited or attached. Polymerized carbon layer 104A has a significantly higher density than mesoporous carbon material 114, thereby providing a structurally robust surface on which to deposit or attach subsequent layers to form anode structure 102. In one embodiment, the density of polymerized carbon layer 104A is greater than the density of mesoporous carbon material 114 by a factor of approximately 2 to 5. In one embodiment, the surface of mesoporous carbon material 114 is treated with a polymerization process to form polymerized carbon layer 104A on mesoporous carbon material 114. In such an embodiment, any known polymerization process may be used to form polymerized carbon layer 104A, including directing ultra-violet and/or infra-red radiation onto the surface of mesoporous carbon material 114. In another embodiment, polymerized carbon layer 104A is deposited in-situ as a final step in the formation of mesoporous carbon material 114. In such an embodiment, one or more process parameters, e.g., hydrocarbon precursor gas temperature, are changed in a final stage of the deposition of mesoporous carbon material 114, so that polymerized carbon layer 104A is formed on mesoporous carbon material 114, as shown.

Dielectric layer 104B comprises a polymeric material and may be deposited as an additional polymeric layer on polymerized carbon layer 104A. Dielectric polymers that may be deposited on polymerized carbon layer 104A to form dielectric layer 104B are discussed above in conjunction with FIG. 1. Alternatively, in one embodiment, polymerized carbon layer 104A may also serve as the dielectric portion of separator layer 104, in which case separator layer 104 consists essentially of a single polymeric material, i.e., polymerized carbon layer 104A.

### Processing System:

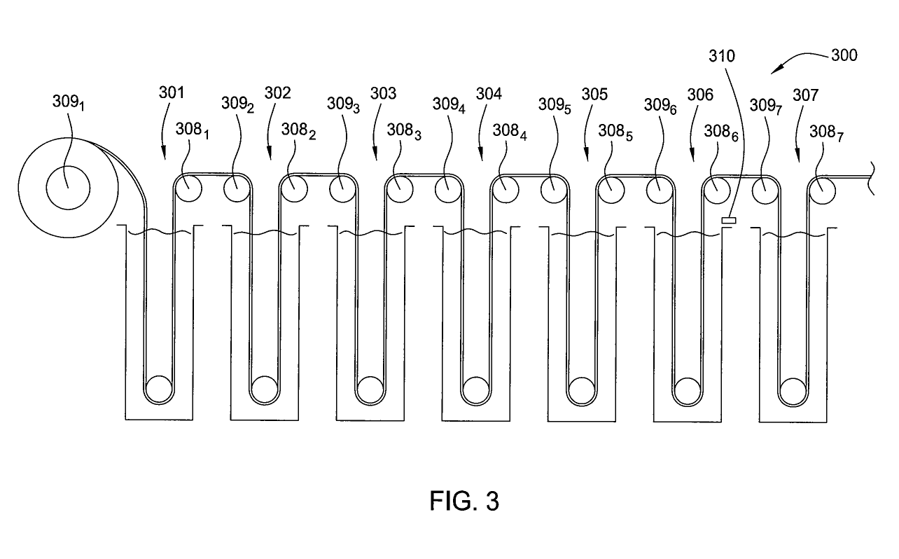

FIG. 3 schematically illustrates a processing system 300 comprising a surface modification chamber 307 which may be used to deposit the passivation film 210 described herein. The processing system 300 generally comprises a plurality of processing chambers arranged in a line, each configured to perform one processing step to a substrate formed on one portion of a continuous flexible substrate 310.

In one embodiment, the processing system 300 comprises a pre-wetting chamber 301 configured to pre-wet a portion of the flexible substrate 310.

The processing system 300 further comprises a first plating chamber 302 configured to perform a first plating process on a portion of the flexible substrate 310. In one embodiment, the first plating chamber 302 is generally disposed next to the cleaning pre-wetting station. In one embodiment, the first plating process may be plating a columnar copper layer on a seed layer formed on the portion of the flexible substrate 310.

In one embodiment, the processing system 300 further comprises a second plating chamber 303 configured to perform a second plating process. In one embodiment, the second plating chamber 303 is disposed next to the first plating chamber 302. In one embodiment, the second plating process is forming a porous layer of copper or alloys on the columnar copper layer.

In one embodiment, the processing system 300 further comprises a rinsing station 304 configured to rinse and remove any residual plating solution from the portion of flexible substrate 310 processed by the second plating chamber 303. In one embodiment, the rinsing station 304 is disposed next to the second plating chamber 303.

In one embodiment, the processing system 300 further comprises a third plating chamber 305 configured to perform a third plating process. In one embodiment, the third plating chamber 305 is disposed next to the rinsing station 304. In one embodiment, the third plating process is forming a thin film over the porous layer. In one embodiment the thin film deposited in the third plating chamber 305 comprises the passivation film 210 described herein. In another embodiment, the thin film deposited in the third plating chamber 305 may comprise an additional conductive film formed over the porous structure 208 such as a tin film.

In one embodiment, the processing system 300 further comprises a rinse-dry station 306 configured to rinse and dry the portion of flexible substrate 310 after the plating processes. In one embodiment, the rinse-dry station 306 is disposed next to the third plating chamber 305. In one embodiment, the rinse-dry station 306 may comprise one or more vapor jets configured to direct a drying vapor toward the flexible substrate 310 as the flexible substrate 310 exits the rinse-dry station 306.

The plating system further comprises a surface modification chamber 307 configured to form passivation film 210 on the portion of the flexible substrate 310 according to embodiments described herein. In one embodiment, the surface modification chamber 310 is disposed next to the rinse-dry station 306. Although the surface modification chamber 307 is shown as a plating chamber it should be understood that the surface modification chamber 307 may comprise another processing chamber selected from the group comprising an electrochemical plating chamber, an electroless deposition chamber, a chemical vapor deposition chamber, a plasma enhanced chemical vapor deposition chamber, an atomic layer deposition chamber, a rinse chamber, an anneal chamber, and combinations thereof. It should also be understood that additional surface modification chambers may be included in the in-line processing system. For example, in certain embodiments, it may be desirable to deposit a portion of the passivation film 210 using electroplating techniques and then deposit the remainder of the film using a CVD or PVD process. In other embodiments, it may be desirable to first deposit a portion of the passivation film 210 using a CVD or PVD process and to deposit the remainder of the passivation film 210 using electroplating techniques. In certain embodiments, it may be desirable to use a PVD process to form a portion of the passivation film 210 and to use a CVD process to form the remainder of the passivation film 210. In certain embodiments it may be desirable to perform a post deposition anneal process after formation of the passivation film 210.

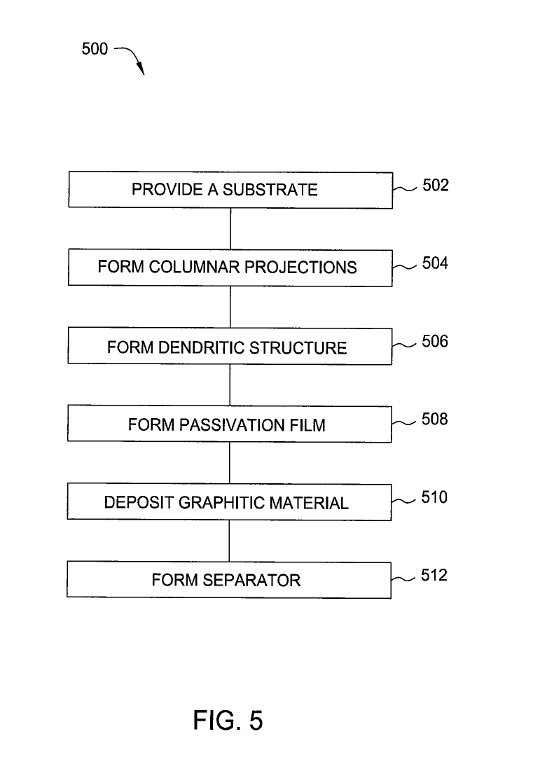

The processing chambers 301-307 are generally arranged along a line so that portions of the flexible substrate 310 can be streamlined through each chamber through feed rolls 309₁₋₇ and take up rolls 308₁₋₇ of each chamber. In one embodiment, the feed rolls 309₁₋₇ and take up rolls 308₁₋₇ may be activated simultaneously during substrate transferring step to move each portion of the flexible substrate 310 one chamber forward. Details of a processing system that can be used with the embodiments described herein are disclosed in commonly assigned U.S. patent application Ser. No. 12/620,788, titled APPARATUS AND METHOD FOR FORMING 3D NANOSTRUCTURE ELECTRODE FOR ELECTROCHEMICAL BATTERY AND CAPACITOR, to Lopatin et al., filed Nov. 18, 2009, now published as US2010-0126849 of which FIGS. 5A-5C, 6A-6E, 7A-7C, and 8A-8D and text corresponding to the aforementioned figures are incorporated by reference herein. It should also be understood that although discussed as a processing system for processing a horizontal substrate, the same processes may be performed on substrates having different orientations, for example, substrate having a vertical orientation. In certain embodiments, the processing chambers 301-307 may be configured to simultaneously form the structures described herein on opposite sides of the flexible substrate.

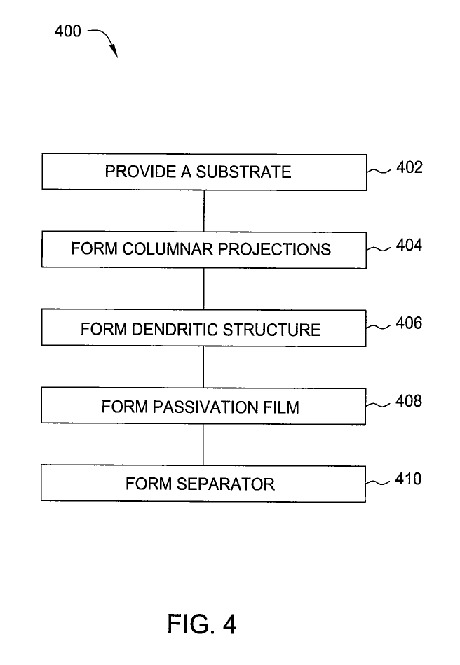

FIG. 4 is a process flow chart summarizing a method 400 for forming an anode structure similar to anode structure 102 as illustrated in FIGS. 1 and 2A-2G, according to embodiments described herein. In block 402, a substrate substantially similar to current collector 111 in FIG. 1 is provided. As detailed above, the substrate may be a conductive substrate, such as metallic foil, or a non-conductive substrate that has an electrically conductive layer formed thereon, such as a flexible polymer or plastic having a metallic coating.

In block 404, conductive columnar projections substantially similar to columnar projections 211 in FIG. 2D are formed on a conductive surface of the substrate 111. In one embodiment, the columnar projections 211 may have a height of 5 to 10 microns and/or have a measured surface roughness of about 10 microns. In another embodiment, the columnar projections 211 may have a height of 15 to 30 microns and/or have a measured surface roughness of about 20 microns. A diffusion-limited electrochemical plating process is used to form columnar projections 211. In one embodiment, the three dimensional growth of columnar projections 211 is performed using a high plating rate electroplating process performed at current densities above the limiting current (i_{L}). Formation of the columnar projections 211 includes establishing process conditions under which evolution of hydrogen results, thereby forming a porous metal film. In one embodiment, such process conditions are achieved by performing at least one of: decreasing the concentration of metal ions near the surface of the plating process; increasing the diffusion boundary layer; and reducing the organic additive concentration in the electrolyte bath. It should be noted that the diffusion boundary layer is strongly related to the hydrodynamic conditions.

Formation of columnar projections 211 may take place in a processing chamber. A processing chamber that may be adapted to perform one or more of the process steps described herein may include an electroplating chamber, such as the SLIMCELL® electroplating chamber available from Applied Materials, Inc. of Santa Clara, Calif. One approach for forming columnar projections 211 is roll-to-roll plating using the processing system 300 described above. Another approach for forming columnar projections 211 is roll-to-roll embossing using the processing system 300 described above where one of the plating chambers is replaced with an embossing chamber. Other processing chambers and systems, including those available from other manufactures may also be used to practice the embodiments described herein.

The processing chamber includes a suitable plating solution. Suitable plating solutions that may be used with the processes described herein include electrolyte solutions containing a metal ion source, an acid solution, and optional additives. Suitable plating solutions are described in U.S. patent application Ser. No. 12/696,422, entitled POROUS THREE DIMENSIONAL COPPER, TIN, COPPER-TIN, COPPER-TIN-COBALT, AND COPPER-TIN-COBALT-TITANIUM ELECTRODES FOR BATTERIES AND ULTRACAPACITORS, filed Jan. 29, 2010, which is incorporated herein by reference to the extent not inconsistent with the current disclosure.

The columnar projections 211 are formed using a diffusion limited deposition process. The current densities of the deposition bias are selected such that the current densities are above the limiting current (i_{L}). The columnar metal film is formed due to the evolution of hydrogen gas and resulting dendritic film growth that occurs due to the mass transport limited process. In one embodiment, during formation of columnar projections 211, the deposition bias generally has a current density of about 10 A/cm² or less. In another embodiment, during formation of columnar projections 211, the deposition bias generally has a current density of about 5 A/cm² or less. In yet another embodiment, during formation of columnar projections 211, the deposition bias generally has a current density of about 3 A/cm² or less. In one embodiment, the deposition bias has a current density in the range from about 0.05 A/cm² to about 3.0 A/cm². In another embodiment, the deposition bias has a current density between about 0.1 A/cm² and about 0.5 A/cm². In yet another embodiment, the deposition bias has a current density between about 0.05 A/cm² and about 0.3 A/cm². In yet another embodiment, the deposition bias has a current density between about 0.05 A/cm² and about 0.2 A/cm². In one embodiment, this results in the formation of columnar projections between about 1 micron and about 300 microns thick on the copper seed layer. In another embodiment, this results in the formation of columnar projections between about 10 microns and about 30 microns. In yet another embodiment, this results in the formation of columnar projections between about 30 microns and about 100 microns. In yet another embodiment, this results in the formation of columnar projections between about 1 micron and about 10 microns, for example, about 5 microns.

In block 406, conductive dendritic structures substantially similar to dendritic structures 208 in FIGS. 2E-G are formed on the substrate or current collector 111. The conductive dendritic structures may be formed on the columnar projections of block 404, or formed directly on the flat conductive surface of the substrate or current collector 111. In one embodiment, an electrochemical plating process may be used to form the conductive dendritic structures, and in another embodiment, an electroless plating process may be used.

The electrochemical plating process for forming conductive dendritic structures similar to dendritic structures 208 involves exceeding the electro-plating limiting current during plating to produce an even lower-density dendritic structure than columnar projections 211 formed at block 404. Otherwise, the process is substantially similar to the electroplating process of block 404 and may be performed in-situ, and thus may be performed immediately following block 404 in the same chamber. The electric potential spike at the cathode during this step is generally large enough so that reduction reactions occur, hydrogen gas bubbles form as a byproduct of the reduction reactions at the cathode, while dendritic structures are constantly being formed on the exposed surfaces. The formed dendrites grow around the formed hydrogen bubbles because there is no electrolyte-electrode contact underneath the bubble. In a way, these microscopic bubbles serve as “templates” for dendritic growth. Consequently, these anodes have many pores when deposited according to embodiments described herein.

In one embodiment, minimizing the size of evolved gas bubbles produces smaller pores in dendritic structures 208. As the bubbles rise, they may combine, or coalesce, with nearby bubbles to form larger dendrite templates. The artifacts remaining from this entire process are relatively large pores in the dendritic growth. In order to maximize surface area of dendritic structures 208, it is preferable to minimize the size of such pores. This can be achieved with the addition of organic additives, such as organic acids.

In sum, when an electrochemical plating process is used to form dendritic structures 208 on columnar projections 211, a columnar microstructure may be formed at a first current density by a diffusion limited deposition process, followed by the three dimensional growth of dendritic structures 208 at a second current density, or second applied voltage, that is greater than the first current density, or first applied voltage.

Alternatively, an electroless deposition process may be used to form dendritic structures 208. In such an embodiment, dendritic structures 208 are comprised of chains of catalytic metal nano-particles. Metal nano-particles known to act as catalysts for forming carbon nano-tubes include iron (Fe), palladium (Pd), platinum (Pt) and silver (Ag), and embodiments of the invention contemplate that the catalytic nano-particles that form dendritic structures 208 may include such catalytic materials. According to one embodiment, the electroless deposition process is achieved by immersing the substrate in a silver nitrate (AgNO₃) solution or other silver salt solution.

In block 408, a passivation film substantially similar to the passivation film 210 in FIGS. 2F-G is formed over the substrate or current collector 111. The passivation film may be formed on the columnar projections and/or dendritic structures of block 406. The passivation film can be formed by a process selected from the group comprising an electrochemical plating process, a chemical vapor deposition process, a plasma enhanced chemical vapor deposition process, a physical vapor deposition process, an electroless process, and combinations thereof. In certain embodiments, the passivation film 210 may be formed using a multi-step process. The passivation film 210 assists in the formation of the solid electrolyte interface (SEI) and provides high capacity and long cycle life for the electrode to be formed.

In one embodiment, the passivation film of block 408 is formed in the same plating chamber as the dendritic structure of block 406. In another embodiment, the passivation film of block 408 is formed in a separate chamber. In certain embodiments, an optional rinse step is performed after formation of the dendritic structure of block 406 and prior to the formation of the passivation film of block 408.

In embodiments where the passivation film of block 408 is formed using electroplating techniques, a deposition bias having a current density of about 10 A/cm² or less, about 6 A/cm² or less, at about 3 A/cm² or less. In one embodiment, the deposition bias has a current density in the range from about 0.005 A/cm² to about 3.0 A/cm². In another embodiment, the deposition bias has a current density between about 0.1 A/cm² and about 0.5 A/cm². In yet another embodiment, the deposition bias has a current density between about 0.05 A/cm² and about 0.2 A/cm². In yet another embodiment, the deposition bias has a current density between about 0.05 A/cm² and about 0.2 A/cm². In one embodiment, this results in the formation of a passivation film between about 1 nm and about 1,000 nm thick on the dendritic structure. In another embodiment, this results in the formation of a passivation film between about 50 nm and about 600 nm. In yet another embodiment, this results in the formation of a passivation between about 100 nm and about 300 nm. In yet another embodiment, this results in the formation of a passivation film between about 150 nm and about 200 nm, for example, about 160 nm. In one embodiment, a voltage between about 0.1 and 1 volt is applied during passivation layer formation. In one embodiment a voltage between about 0.3 volts and 0.4 volts is applied during passivation layer formation. Alternately, chemical vapor deposition techniques (e.g., thermal chemical vapor deposition, plasma enhanced chemical vapor deposition, hot-wire chemical vapor deposition, and initiated chemical vapor deposition) may be used either in lieu of or in conjunction with the electroplating techniques. In such embodiments, the passivation film may comprise silicon containing materials deposited using CVD techniques.

In certain embodiments, there the passivation film of block 408 is a lithium containing passivation film, lithium may be added to the film either during first charge or through a pre-lithiation process where lithium is inserted into the passivation film by exposing the passivation film to a lithium containing solution. Lithium containing solutions include but are not limited to lithium hydroxide (LiOH), lithium chloride (LiCl), lithium sulfate (Li₂SO₄), lithium carbonate (Li₂CO₄), and combinations thereof.

In embodiments where the passivation film of block 408 is a silicon containing passivation the passivation film may be formed using a process gas mixture including but not limited to a silicon containing gas selected from the group comprising silane (SiH₄), disilane, chlorosilane, dichlorosilane, trimethylsilane, and tetramethylsilane, tetraethoxysilane (TEOS), triethoxyfluorosilane (TEFS), 1,3,5,7-tetramethylcyclotetrasiloxane (TMCTS), dimethyldiethoxy silane (DMDE), octomethylcyclotetrasiloxane (OMCTS), and combinations thereof. Flow rates for a process gas mixture comprising a silicon containing gas may be between 30 sccm and 3,000 sccm per chamber volume of 2,000 cm³. For a thermal CVD process, a chamber pressure of between about 0.3 to 3 Torr, for example, about 0.5 Torr, may be maintained in the chamber, and a temperature between 150° C. and 450° C. may be maintained in the chamber. Optionally, a carrier gas is introduced into the chamber at a flow rate of between about 0 sccm and about 20,000 sccm. The carrier gas may be nitrogen gas or an inert gas.

For a silicon containing passivation film formed using PECVD techniques, a chamber pressure of between about 0.3 to 3 Torr, for example, about 0.5 Torr, may be maintained in the chamber, a temperature between 150° C. and 450° C. may be maintained in the chamber, and an RF power intensity of between 30 mW/cm² and 200 mW/cm², for example, about 60 mW/cm², at a frequency of 13.56 MHz may be applied to the electrodes of the chamber to generate a plasma. Alternatively, low frequency RF power, e.g., 400 kHz, may instead be applied to the electrodes.

Alternately, physical vapor deposition processes (PVD) such as sputtering, or an evaporation process may be used either in lieu of or in conjunction with the aforementioned electroplating and chemical vapor deposition techniques to deposit the passivation film or a portion of the passivation film.

Optionally, the substrate may be annealed after formation of the passivation film. During the annealing process, the substrate may be heated to a temperature in a range from about 100° C. to about 250° C., for example, between about 150° C. and about 190° C. Generally, the substrate may be annealed in an atmosphere containing at least one anneal gas, such as O₂, N₂, NH₃, N₂H₄, NO, N₂O, or combinations thereof. In one embodiment, the substrate may be annealed in ambient atmosphere. The substrate may be annealed at a pressure from about 5 Torr to about 100 Torr, for example, at about 50 Torr. In certain embodiments, the annealing process serves to drive out moisture from the pore structure. In certain embodiments, the annealing process serves to diffuse atoms into the copper base, for example, annealing the substrate allows tin atoms to diffuse into the copper base, making a much stronger copper-tin layer bond.

In block 410, a separator layer is formed. In one embodiment, the separator layer is a dielectric, porous, fluid-permeable layer that prevents direct electrical contact between the components in the anode structure and the cathode structure. Alternatively, the separator layer is deposited onto the surface of the dendritic structure and may be a solid polymer, such as polyolefin, polypropylene, polyethylene, and combinations thereof. In one embodiment, the separator layer comprises a polymerized carbon layer comprising a densified layer of mesoporous carbon material on which a dielectric layer may be deposited or attached.

FIG. 5 is a process flow chart summarizing another method 500 for forming an anode structure according to embodiments described herein. The method 500 is substantially similar to the method 400 described above in blocks 402-410 except a graphitic material is deposited in block 510 after formation of the passivation film in block 508 and prior to formation of the a separator in block 512.

In block 512, the graphitic material may be deposited in the pores of the dendritic structure to form a hybrid layer prior to formation of the separator layer. Graphite is usually used as the active electrode material of the negative electrode and can be in the form of a lithium-intercalation meso carbon micro beads (MCMB) powder made up of MCMBs having a diameter of approximately 10 μm. The lithium-intercalation MCMB powder is dispersed in a polymeric binder matrix. The polymers for the binder matrix are made of thermoplastic polymers including polymers with rubber elasticity. The polymeric binder serves to bind together the MCMB material powders to preclude crack formation and prevent disintegration of the MCMB powder on the surface of the current collector. In one embodiment, the quantity of polymeric binder is in the range of 2% to 30% by weight.

In certain embodiments, the graphitic material or meso-porous structure may be formed prior to the formation of the passivation film.

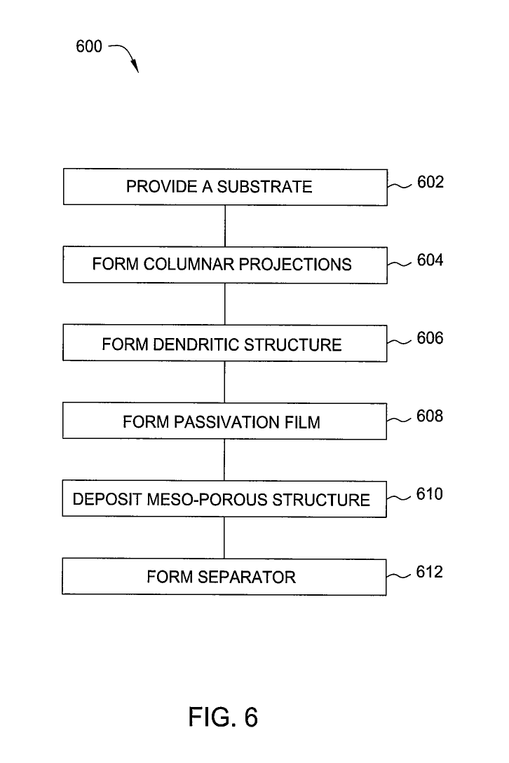

FIG. 6 is a process flow chart summarizing a method 600 for forming an anode structure according to embodiments described herein. The method 600 is substantially similar to the method 400 described above in blocks 402-410 except a meso-porous structure is deposited in block 610 after formation of the passivation film in block 608 and prior to formation of a separator in block 612. The meso-porous structure may be deposited as described above.

### EXAMPLES

The following hypothetical non-limiting examples are provided to further illustrate embodiments described herein. However, the examples are not intended to be all inclusive and are not intended to limit the scope of the embodiments described herein.

### Copper-Containing Passivation Films:

### Copper-Oxide Passivation Film

A copper-oxide passivation film was prepared as follows: a substrate comprising a three dimensional porous copper anode structure was immersed in a plating solution in an electroplating chamber comprising a Pt(Ti) anode with a surface area of about 3 cm². The plating solution initially comprised 1.0 M sulfuric acid, 0.28 M copper sulfate, and 200 ppm of citric acid. The copper oxide passivation film was formed on the three dimensional porous anode structure at a current density of about 1 A/cm². The process was performed at room temperature. In one embodiment, the plating solution also comprises 0.45% by volume of an oxidizer such as hydrogen peroxide.

### Copper-Chloride Passivation Film

A copper-chloride passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.32 M copper chloride, and 200 ppm of citric acid. The copper chloride passivation film was formed on the three dimensional porous anode structure at a current density of about 2 A/cm². The process was performed at room temperature.

### Copper-Sulfide Passivation Film

A copper-sulfide passivation film was prepared as follows: a substrate comprising a three dimensional porous copper anode structure was immersed in a plating solution in an electroplating chamber comprising a Pt(Ti) anode with a surface area of about 1 m². The plating solution initially comprised 1.0 M sulfuric acid, 0.28 M copper sulfate, and 200 ppm of citric acid. The copper sulfide passivation film was formed on the three dimensional porous anode structure at a current density of about 0.5 A/cm². The process was performed at room temperature.

### Copper-Nitrile Passivation Film

A copper-nitrile passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.1M copper cyanide, and 200 ppm of citric acid. The copper nitrile passivation film was formed on the three dimensional porous anode structure at a current density of about 2 A/cm². The process was performed at room temperature.

### Copper-Carbonate Passivation Film

A copper-carbonate passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.30 M copper carbonate, and 200 ppm of citric acid. The copper carbonate passivation film was formed on the three dimensional porous anode structure at a current density of about 1 A/cm². The process was performed at room temperature.

### Copper-Phosphide Passivation Film

A copper-phosphide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper pyrophosphate, and 200 ppm of citric acid. The copper pyrophosphate passivation film was formed on the three dimensional porous anode structure at a current density of about 2 A/cm². The process was performed at room temperature.

### Copper-Tin-Oxide Passivation Film

A copper-tin-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.15 M stannous sulfate, and 200 ppm of citric acid. The copper tin oxide passivation film was formed on the three dimensional porous anode structure at a current density of about 0.5 A/cm². The process was performed at room temperature. In one embodiment, the plating solution also comprises 0.50% by volume of an oxidizer such as hydrogen peroxide.

### Copper-Cobalt-Oxide Passivation Film

A copper-cobalt-oxide passivation film was prepared as follows: a substrate comprising a three dimensional porous copper anode structure was immersed in a plating solution in an electroplating chamber comprising a Pt(Ti) anode with a surface area of about 3 cm². The plating solution initially comprised 1.0 M sulfuric acid, 0.28 M copper sulfate, 0.15 M cobalt sulfate, and 200 ppm of citric acid. The copper-cobalt-oxide passivation film was formed on the three dimensional porous anode structure at a current density of about 1 A/cm². The process was performed at room temperature. In one embodiment, the plating solution also comprises 0.30% by volume of an oxidizer such as hydrogen peroxide.

### Copper-Cobalt-Tin-Titanium-Oxide Passivation Film

A copper-cobalt-tin-titanium-oxide passivation film was prepared as follows: a substrate comprising a three dimensional porous copper anode structure with a titanium layer deposited thereon was immersed in a plating solution in an electroplating chamber comprising a Pt(Ti) anode with a surface area of about 25 cm². The plating solution initially comprised 1.0 M sulfuric acid, 0.28 M copper sulfate, 0.17 M stannous sulfate, 0.15 cobalt sulfate, and 200 ppm of citric acid. The copper-cobalt-tin-titanium-oxide passivation film was formed on the three dimensional porous anode structures at a current density of about 1.5 A/cm². The process was performed at room temperature. In one embodiment, the plating solution also comprises 0.90% by volume of an oxidizer such as hydrogen peroxide.

### Copper-Silicon-Oxide Passivation Film

A copper-silicon-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, and 200 ppm of citric acid. A copper-oxide passivation film was formed on the three dimensional porous anode structures at a current density of about 0.8 A/cm². The process was performed at room temperature. The copper-oxide passivation film was then transferred to a chemical vapor deposition chamber and exposed to silane gas at a flow rate of 1,000 sccm, a chamber pressure of about 0.5 Torr, and a temperature of 250° C. were maintained during a thermal CVD process to form the copper-silicon-oxide passivation film.

### Lithium-Containing Passivation Films:

### Lithium-Copper-P—O—N Passivation Film

A phosphorous oxynitride passivation film was prepared as follows: a substrate with a surface area of about 5 cm² comprising a three dimensional porous copper anode structure was placed in a chemical vapor deposition (CVD) chamber. An oxynitride film was deposited on the three dimensional porous copper nitride using known CVD techniques. A phosphorous dopant was flowed during the CVD process. The phosphorous-oxynitride film was then exposed to 0.1 M LiOH or LiCl aqueous solution to form the lithium phosphorous-oxynitride passivation film.

### Lithium-Copper-B—O—N Passivation Film

A boron oxynitride passivation film was prepared as follows: A boron oxynitride passivation film was prepared as follows: a substrate with a surface area of about 10 cm² comprising a three dimensional porous copper anode structure was placed in a chemical vapor deposition (CVD) chamber. An oxynitride film was deposited on the three dimensional porous copper nitride using known CVD techniques. A boron dopant was flowed during the CVD process. The boron-oxynitride film was then exposed to 0.1M LiOH or LiCl aqueous solution to form the lithium boron-oxynitride passivation film.

### Lithium-Copper-Oxide Passivation Film

A lithium copper-oxide passivation film was prepared as follows: a substrate comprising a three dimensional porous copper anode structure was immersed in a plating solution in an electroplating chamber comprising a Pt(Ti) anode with a surface area of about 1 m². The plating solution initially comprised 1.0 M sulfuric acid, 0.28 M copper sulfate, and 200 ppm of citric acid. The process was performed at room temperature. A copper oxide film was formed on the three dimensional porous anode structures at a current density of about 0.5 A/cm². The copper oxide film was then exposed to 0.1M LiOH or LiCl aqueous solution to form the lithium copper-oxide passivation film. In one embodiment, the plating solution also comprises 0.70% by volume of an oxidizer such as hydrogen peroxide.

A lithium copper-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, and 200 ppm of citric acid. The process was performed at room temperature. A copper oxide film was formed on the three dimensional porous anode structure at a current density of about 2 A/cm². The three dimensional porous anode structure and copper oxide film was coupled with a separator and a cathode structure to form a working cell of a battery. The working cell contained an electrolyte comprising LiPF₆ and an ethylene oxide solvent. Lithium from the lithium electrolyte is inserted into the copper oxide film to form the lithium-copper-oxide passivation film after the first charge of the working cell. In one embodiment, the plating solution also comprises 0.45% by volume of an oxidizer such as hydrogen peroxide.

### Lithium-Copper-Silicon-Oxide Passivation Film

A lithium-copper-silicon-oxide passivation film was prepared as follows: a substrate comprising a three dimensional porous copper anode structure was exposed to a plating solution in an electroplating chamber comprising a Pt(Ti) anode with a surface area of about 25 cm². The plating solution initially comprised 1.0 M sulfuric acid, 0.28 M copper sulfate, and 200 ppm of citric acid. A copper-oxide film was formed on the three dimensional porous anode structure at a current density of about 3 A/cm². The process was performed at room temperature. The copper-oxide passivation film was then transferred to a chemical vapor deposition chamber and exposed to silane gas at a flow rate of 1,000 sccm, a chamber pressure of about 0.5 Torr, and a temperature of 250° C. were maintained during a thermal CVD process to form a copper-silicon-oxide film. The three dimensional porous anode structure and copper-silicon-oxide film was coupled with a separator and a cathode structure to form a working cell of a battery. The working cell containing an electrolyte comprising LiPF₆ and an ethylene oxide solvent. Lithium from the lithium electrolyte is inserted into the copper-silicon-oxide film to form the lithium-copper-silicon-oxide passivation film after the first charge of the working cell.

### Lithium-Copper-Nickel Oxide Passivation Film

A lithium copper-nickel-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.3 M nickel sulfate, and 200 ppm of citric acid. The process was performed at room temperature. A copper-nickel-oxide film was formed on the three dimensional porous anode structure at a current density of about 1 A/cm². The copper-nickel-oxide film was then exposed to 0.1 M LiOH or LiCl aqueous solution to form the lithium-copper-nickel passivation film.

A lithium copper-nickel-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.3 M nickel sulfate, and 200 ppm of citric acid. The process was performed at room temperature. A copper-nickel-oxide film was formed on the three dimensional porous anode structures at a current density of about 0.5 A/cm². The three dimensional porous anode structure and copper-nickel-oxide film was coupled with a separator and a cathode structure to form a working cell of a battery. The working cell containing an electrolyte comprising LiPF₆ and an ethylene oxide solvent. Lithium from the lithium electrolyte is inserted into the copper-silicon-oxide film to form the lithium-copper-silicon-oxide passivation film after the first charge of the working cell.

### Lithium-Copper-Tin-Oxide Passivation Film

A lithium-copper-tin-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.15 M stannous sulfate, and 200 ppm of citric acid. The copper-tin-oxide film was formed on the three dimensional porous anode structure at a current density of about 1 A/cm². The process was performed at room temperature. The three dimensional porous anode structure and copper-tin-oxide film was coupled with a separator and a cathode structure to form a working cell of a battery. The working cell was filled with an electrolyte comprising LiPF₆ and an ethylene oxide solvent. Lithium from the lithium electrolyte was inserted into the copper-tin-oxide film to form the lithium-copper-tin-oxide passivation film after the first charge of the working cell.

A lithium-copper-tin-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.15 M stannous sulfate, and 200 ppm of citric acid. The copper-tin-oxide film was formed on the three dimensional porous anode structure at a current density of about 2 A/cm². The process was performed at room temperature. The copper-tin-oxide film was then exposed to 0.1 M LiOH or LiCl aqueous solution to form the lithium-copper-tin-oxide passivation film.

### Lithium-Copper-Cobalt-Oxide Passivation Film

A copper-cobalt-oxide film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 0.15 M cobalt sulfate, and 200 ppm of citric acid. The copper-cobalt-oxide film was formed on the three dimensional porous anode structure at a current density of about 1 A/cm². The process was performed at room temperature. The three dimensional porous anode structure and copper-cobalt-oxide film were coupled with a separator and a cathode structure to form a working cell of a battery. The working cell was filled with an electrolyte comprising LiPF₆ and an ethylene oxide solvent. Lithium from the lithium electrolyte was inserted into the copper-cobalt-oxide film to form the lithium-copper-cobalt-oxide passivation film after the first charge of the working cell.

A copper-cobalt-oxide film was prepared as follows: a substrate comprising a three dimensional porous copper anode structure was immersed in a plating solution in an electroplating chamber comprising a Pt(Ti) anode with a surface area of about 3 cm². The plating solution initially comprised 1.0 M sulfuric acid, 0.28 M copper sulfate, 0.15 M cobalt sulfate, and 200 ppm of citric acid. The copper-cobalt-oxide film was formed on the three dimensional porous anode structure at a current density of about 1 A/cm². The process was performed at room temperature. The copper-cobalt-oxide film was then exposed to 0.1 M LiOH or LiCl aqueous solution to form the lithium-copper-cobalt-oxide passivation film.

### Lithium-Copper-Cobalt-Tin-Titanium-Oxide Passivation Film

A lithium-copper-cobalt-tin-titanium-oxide passivation film was prepared as follows: a substrate comprising a three dimensional porous copper anode structure with a titanium layer deposited thereon was immersed in a plating solution in an electroplating chamber comprising a Pt(Ti) anode with a surface area of about 25 cm². The plating solution initially comprised 1.0 M sulfuric acid, 0.28 M copper sulfate, 0.17 M stannous sulfate, 0.15 cobalt sulfate, and 200 ppm of citric acid. A copper-cobalt-tin-titanium-oxide film was formed on the three dimensional porous anode structures at a current density of about 1.5 A/cm². The process was performed at room temperature. The three dimensional porous anode structure and the copper-cobalt-tin-titanium-oxide film were coupled with a separator and a cathode structure to form a working cell of a battery. The working cell was filled with an electrolyte comprising LiPF₆ and an ethylene oxide solvent. Lithium from the lithium electrolyte was inserted into the copper-cobalt-tin-titanium-oxide film to form the lithium-copper-cobalt-tin-titanium-oxide passivation film after the first charge of the working cell.

A lithium-copper-cobalt-tin-titanium-oxide passivation film was prepared as follows: a substrate comprising a three dimensional porous copper anode structure with a titanium layer deposited thereon was immersed in a plating solution in an electroplating chamber comprising a Pt(Ti) anode with a surface area of about 25 cm². The plating solution initially comprised 1.0 M sulfuric acid, 0.28 M copper sulfate, 0.17 M stannous sulfate, 0.15 cobalt sulfate, and 200 ppm of citric acid. A copper-cobalt-tin-titanium-oxide film was formed on the three dimensional porous anode structure at a current density of about 6 A/cm². The process was performed at room temperature. The copper-tin-oxide film was then exposed to 0.1 M LiOH or LiCl aqueous solution to form the lithium-copper-cobalt-tin-titanium-oxide passivation film.

### Lithium-Copper-Cobalt-Nickel-Aluminum-Oxide Passivation Film

A lithium-copper-cobalt-nickel-aluminum-oxide passivation film was prepared as follows: a substrate comprising a three dimensional porous copper anode structure with an aluminum layer deposited thereon using sputtering techniques was immersed in a plating solution in an electroplating chamber comprising a Pt(Ti) anode with a surface area of about 1 m². The plating solution initially comprised 1.0 M sulfuric acid, 0.28 M copper sulfate, 0.15 cobalt sulfate, 0.3 M nickel sulfate, and 200 ppm of citric acid. A copper-cobalt-nickel-aluminum-oxide film was formed on the three dimensional porous anode structure at a current density of about 2 A/cm². The process was performed at room temperature. The copper-cobalt-nickel-aluminum-oxide film was then exposed to 0.1M LiOH or LiCl aqueous solution to form the lithium-copper-cobalt-nickel-aluminum-oxide passivation film.

A lithium-copper-cobalt-nickel-aluminum-oxide passivation film was prepared as follows: a substrate comprising a three dimensional porous copper anode structure with an aluminum layer deposited thereon using sputtering techniques was immersed in a plating solution in an electroplating chamber comprising a Pt(Ti) anode with a surface area of about 1 m². The plating solution initially comprised 1.0 M sulfuric acid, 0.28 M copper sulfate, 0.15 cobalt sulfate, 0.3 M nickel sulfate, and 200 ppm of citric acid. A copper-cobalt-nickel-aluminum-oxide film was formed on the three dimensional porous anode structure at a current density of about 2 A/cm². The process was performed at room temperature. The three dimensional porous anode structure and the copper-cobalt-nickel-aluminum-oxide film were coupled with a separator and a cathode structure to form a working cell of a battery. The working cell was filled with an electrolyte comprising LiPF₆ and an ethylene oxide solvent. Lithium from the lithium electrolyte was inserted into the copper-cobalt-nickel-aluminum-oxide film to form the lithium-copper-cobalt-nickel-aluminum-oxide passivation film after the first charge of the working cell.

### Lithium-Copper-Titanium Oxide Passivation Film

A lithium-copper-titanium-oxide passivation film was prepared as follows: a substrate comprising a three dimensional porous copper anode structure with a titanium layer deposited thereon was immersed in a plating solution in an electroplating chamber comprising a Pt(Ti) anode with a surface area of about 25 cm². The plating solution initially comprised 1.0 M sulfuric acid, 0.28 M copper sulfate, and 200 ppm of citric acid. A copper-oxide film was formed on the three dimensional porous anode structure at a current density of about 3 A/cm². The process was performed at room temperature. The three dimensional porous anode structure and the copper-titanium-oxide film were coupled with a separator and a cathode structure to form a working cell of a battery. The working cell was filled with an electrolyte comprising LiPF₆ and an ethylene oxide solvent. Lithium from the lithium electrolyte was inserted into the copper-titanium-oxide film to form the lithium-copper-titanium-oxide passivation film after the first charge of the working cell.

A lithium-copper-titanium-oxide passivation film was prepared as follows: a substrate comprising a three dimensional porous copper anode structure with a titanium layer deposited thereon was immersed in a plating solution in an electroplating chamber comprising a Pt(Ti) anode with a surface area of about 25 cm². The plating solution initially comprised 1.0 M sulfuric acid, 0.28 M copper sulfate, and 200 ppm of citric acid. A copper-oxide film was formed on the three dimensional porous anode structure at a current density of about 3 A/cm². The process was performed at room temperature. The copper-titanium-oxide film was then exposed to 0.1M LiOH or LiCl aqueous solution to form the lithium-copper-titanium-oxide passivation film.

### Lithium-Aluminum-Silicon Passivation Film

A lithium-aluminum-silicon passivation film was prepared as follows: a substrate comprising a three dimensional porous copper anode structure with an aluminum layer deposited thereon using sputtering techniques was placed in a chemical vapor deposition chamber. The three dimensional porous electrode with the aluminum layer was exposed to silane gas at a flow rate of 1,000 sccm, a chamber pressure of about 0.5 Torr, and a temperature of 250° C. were maintained during a thermal CVD process to form an aluminum silicon film. The aluminum-silicon film was then exposed to 0.1M LiOH or LiCl aqueous solution to form the lithium-aluminum-silicon passivation film.

A lithium-aluminum-silicon passivation film was prepared as follows: a substrate comprising a three dimensional porous copper anode structure with an aluminum layer deposited thereon using sputtering techniques was placed in a chemical vapor deposition chamber. The three dimensional porous electrode with the aluminum layer deposited thereon was exposed to silane gas at a flow rate of 1,000 sccm, a chamber pressure of about 0.5 Torr, and a temperature of 250° C. were maintained during a thermal CVD process to form an aluminum silicon film. The three dimensional porous anode structure and aluminum silicon film were coupled with a separator and a cathode structure to form a working cell of a battery. The working cell containing an electrolyte comprising LiPF₆ and an ethylene oxide solvent. Lithium from the lithium electrolyte is inserted into the aluminum silicon film to form the lithium-aluminum-silicon passivation film after the first charge of the working cell.

### Lithium-Copper-Manganese-Oxide Passivation Film

A lithium-copper-manganese-oxide passivation film was prepared as follows: a substrate comprising a three dimensional porous copper anode structure was immersed in a plating solution in an electroplating chamber comprising a Pt(Ti) anode with a surface area of about 3 cm². The plating solution initially comprised 1.0 M sulfuric acid, 0.28 M copper sulfate, 200 ppm of citric acid, and 300 ppm of manganese. The process was performed at room temperature. A copper manganese oxide film was formed on the three dimensional porous anode structures at a current density of about 1.5 A/cm². The copper manganese oxide film was then exposed to 0.1M LiOH or LiCl aqueous solution to form the lithium copper-oxide passivation film.

A lithium copper-manganese-oxide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper sulfate, 200 ppm of citric acid, and 300 ppm of manganese oxide. The process was performed at room temperature. A copper manganese oxide film was formed on the three dimensional porous anode structure at a current density of about 3 A/cm². The three dimensional porous anode structure and copper manganese oxide film was coupled with a separator and a cathode structure to form a working cell of a battery. The working cell containing an electrolyte comprising LiPF₆ and an ethylene oxide solvent. Lithium from the lithium electrolyte is inserted into the copper oxide film to form the lithium-copper-oxide passivation film after the first charge of the working cell.

### Lithium-Copper-Iron-Phosphide Passivation Film

A lithium-copper-iron-phosphide passivation film was prepared as follows: a substrate comprising a three dimensional porous copper anode structure was immersed in a plating solution in an electroplating chamber comprising a Pt(Ti) anode with a surface area of about 25 cm². The plating solution initially comprised 1.0 M sulfuric acid, 0.28 M copper pyrophosphate, 200 ppm of citric acid, and 300 ppm of iron oxide. The copper-iron-phosphide film was formed on the three dimensional porous anode structure at a current density of about 2 A/cm². The process was performed at room temperature. The copper-iron-phosphide film was then exposed to 0.1M LiOH or LiCl aqueous solution to form the lithium-copper-iron-phosphide passivation film.

A lithium-copper-iron-phosphide passivation film was prepared as follows: a substrate comprising a three dimensional porous copper anode structure was immersed in a plating solution in an electroplating chamber comprising a Pt(Ti) anode with a surface area of about 1 m². The plating solution initially comprised 1.0 M sulfuric acid, 0.28 M copper pyrophosphate, 200 ppm of citric acid, and 200 ppm of iron oxide. The copper-iron-phosphide film was formed on the three dimensional porous anode structure at a current density of about 1 A/cm². The process was performed at room temperature. The three dimensional porous anode structure and copper-iron-phosphide film was coupled with a separator and a cathode structure to form a working cell of a battery. The working cell containing an electrolyte comprising LiPF₆ and an ethylene oxide solvent. Lithium from the lithium electrolyte is inserted into the copper-iron-phosphide film to form the lithium-copper-iron-phosphide passivation film after the first charge of the working cell.

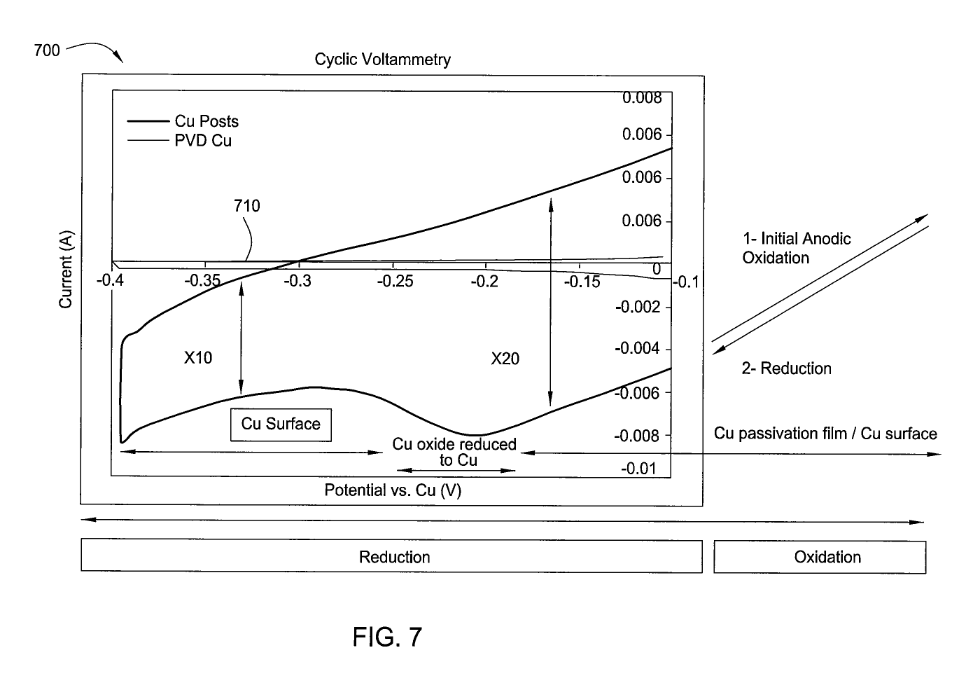

FIG. 7 illustrates a plot 700 demonstrating the effect of a passivation film formed according to embodiments described herein on storage capacity for energy storage devices. The Y-axis represents current measured in amperes (A) and the X-axis represents potential verses copper measured in volts (V). The results were obtained using cyclic voltammetry techniques. The tests were performed on copper columnar structures deposited on a copper foil substrate. Exemplary cyclic voltammetry techniques are described in commonly assigned U.S. patent application Ser. No. 12/368,105, entitled METROLOGY METHODS AND APPARATUS FOR NANOMATERIAL CHARACTERIZATION OF ENERGY STORAGE ELECTRODE STRUCTURES, filed on Feb. 29, 2009, which is incorporated herein by reference to the extent not inconsistent with the embodiments described herein. The results of the plot 700 demonstrate that an initial voltage sweep in the oxidation direction results in the formation of a copper passivation film on the surface of a copper columnar structure. It is believed that the copper passivation film increases the charge storage capacity of the electrode by twenty times relative to the charge storage capacity of copper foil which is represented by line 710. However, if the initial voltage sweep is in the reduction direction where no copper passivation film is formed, the charge storage capacity of the electrode is only increased by ten times relative to the storage capacity of copper foil alone. Thus it is believed that the formation of a passivation film on an electrode results in a larger charge storage capacity for an electrode. It is further believed that deposition of a copper film on a three dimensional dendritic structure and columnar layer could result in charge storage capacities of at least fifty times and possibly two-hundred and fifty times that of copper foil alone.

While the foregoing is directed to embodiments of the present invention, other and further embodiments of the invention may be devised without departing from the basic scope thereof, and the scope thereof is determined by the claims that follow.

1. An anodic structure used to form an energy storage device, comprising:
a conductive substrate;
a plurality of conductive microstructures formed on the substrate;
a passivation film formed over the conductive microstructures; and
an insulative separator layer formed over the conductive microstructures, wherein the conductive microstructures comprise columnar projections.

2. The anodic structure of claim 1, wherein the passivation film comprises a material selected from the group comprising copper oxides, copper chlorides, copper sulfides, copper-nitriles, copper-carbonates, copper-phosphides, copper-tin oxides, copper-cobalt-tin oxides, copper-cobalt-tin-titanium oxides, copper-silicon oxides, copper-nickel oxides, copper-cobalt oxides, copper-cobalt-tin-titanium oxides, copper-cobalt-nickel-aluminum oxides, copper-titanium oxides, copper manganese oxides, copper iron phosphates, lithium-copper-P—O—N, lithium-copper-B—O—N, lithium-copper-oxides, lithium-copper-silicon oxides, lithium-copper-nickel oxides, lithium-copper-tin oxides, lithium-copper-cobalt oxides, lithium-copper-cobalt-tin-titanium oxides, lithium-copper-cobalt-nickel-aluminum oxides, lithium-copper-titanium oxides, lithium-aluminum-silicon, lithium-copper-manganese oxides, lithium-copper-iron-phosphides, aluminum-silicon, and combinations thereof.

3. The anodic structure of claim 1, wherein the conductive microstructures further comprise dendritic structures formed by an electroplating process or an electroless process.

4. The anodic structure of claim 1, wherein the conductive microstructures comprise a macro-porous structure having macro-pores of between about 5 and about 100 microns (μm) in diameter.

5. The anodic structure of claim 4, wherein the conductive microstructures further comprise a meso-porous structure having a plurality of meso-pores that are between about 100 nm to about 1,000 nm in diameter.

6. The anodic structure of claim 5, wherein the conductive microstructures further comprise a nano-porous structure having a plurality of nano-pores having a diameter less than about 100 nm.

7. The anodic structure of claim 1, wherein the conductive microstructure comprises a material selected from a group comprising: copper, zinc, nickel, cobalt, palladium, platinum, tin, ruthenium, alloys thereof, and combinations thereof.

8. The anodic structure of claim 1, wherein the passivation film has a thickness between about 1 nm and about 1,000 nm.

9. The anodic structure of claim 1, wherein the conductive substrate comprises a metallic foil.

10. The anodic structure of claim 1, further comprising a meso-porous carbon containing material formed between the passivation film and the insulative separator layer.

11. A method for forming an anodic structure, comprising:
depositing a plurality of conductive microstructures on a conductive substrate; and
forming a passivation film over the conductive microstructures.

12. The method of claim 11, further comprising:
forming an insulative separator layer over the conductive microstructures, wherein the conductive microstructures comprises columnar projections formed via an electroplating process.

13. The method of claim 11, wherein the passivation film comprises a material selected from the group comprising copper oxides, copper chlorides, copper sulfides, copper-nitriles, copper-carbonates, copper-phosphides, copper-tin oxides, copper-cobalt-tin oxides, copper-cobalt-tin-titanium oxides, copper-silicon oxides, copper-nickel oxides, copper-cobalt oxides, copper-cobalt-tin-titanium oxides, copper-cobalt-nickel-aluminum oxides, copper-titanium oxides, copper manganese oxides, copper iron phosphates, lithium-copper-P—O—N, lithium-copper-B—O—N, lithium-copper-oxides, lithium-copper-silicon oxides, lithium-copper-nickel oxides, lithium-copper-tin oxides, lithium-copper-cobalt oxides, lithium-copper-cobalt-tin-titanium oxides, lithium-copper-cobalt-nickel-aluminum oxides, lithium-copper-titanium oxides, lithium-aluminum-silicon, lithium-copper-manganese oxides, lithium-copper-iron-phosphides, aluminum-silicon, and combinations thereof.

14. The method of claim 11, wherein depositing a plurality of conductive microstructures on the conductive substrate, comprises:
depositing a columnar microstructure over the conductive substrate at a first current density by a diffusion limited deposition process; and
depositing a conductive dendritic structure over the columnar microstructure at a second current density greater than the first current density.

15. The method of claim 14, wherein the passivation film is deposited by applying a third current density less than the first current density.

16. The method of claim 11, further comprising:
forming a meso-porous carbon layer over the passivation film; and
forming an insulative separator layer over the meso-porous carbon layer.

17. The method of claim 11, further comprising:
forming a graphitic carbon layer over the passivation film; and
forming an insulative separator layer over the graphitic carbon layer.

18. The method of claim 11, wherein the conductive microstructure comprises a material selected from a group comprising: copper, zinc, nickel, cobalt, palladium, platinum, tin, ruthenium, alloys thereof, and combinations thereof.

19. The method of claim 11, wherein the diffusion limited deposition process comprises a high plating rate electroplating process performed at current densities above the limiting current (i_{L}).

20. The method of claim 15, wherein:
the first current density is between about 0.05 A/cm² to about 3.0 A/cm²;
the second current density is between about 0.3 A/cm² to about 3.0 A/cm²; and
the third current density is between about 0.05 A/cm² to about 3.0 A/cm².

21. The method of claim 15, wherein:
the columnar microstructure comprises copper and the first current density is between about 0.1 A/cm² to about 0.5 A/cm²;
the dendritic structure comprises copper and the second current density is between about 1 A/cm² to about 2 A/cm²; and
the passivation film comprises copper-oxide and the third current density is between about 0.1 A/cm² to about 0.5 A/cm².

22. The method of claim 11, wherein the passivation film can be formed by a process selected from the group comprising an electrochemical plating process, a chemical vapor deposition process, a plasma enhanced chemical vapor deposition process, a physical vapor deposition process, an electroless process, and combinations thereof.

23. A substrate processing system for processing a flexible substrate, comprising:
a first plating chamber configured to plate a conductive microstructure comprising a first conductive material over a portion of the flexible substrate;
a first rinse chamber disposed adjacent to the first plating chamber configured to rinse and remove any residual plating solution from the portion of the flexible substrate with a rinsing fluid;
a second plating chamber disposed adjacent to the first rinse chamber configured to deposit a second conductive material over the conductive microstructures;
a second rinse chamber disposed adjacent to the second plating chamber configured to rinse and remove any residual plating solution from the portion of the flexible substrate;
a surface modification chamber configured to form a passivation film on the portion of the flexible substrate;
a substrate transfer mechanism configured to transfer the flexible substrate among the chambers, comprising:
a feed roll configured to retain a portion of the flexible substrate; and
a take up roll configured to retain a portion of the flexible substrate, wherein the substrate transfer mechanism is configured to activate the feed rolls and the take up rolls to move the flexible substrate in and out of each chamber, and hold the flexible substrate in a processing volume of each chamber.

24. The substrate processing system of claim 23, wherein the surface modification chamber is selected from the group comprising an electrochemical plating chamber, an electroless deposition chamber, a chemical vapor deposition chamber, a plasma enhanced chemical vapor deposition chamber, an atomic layer deposition chamber, a rinse chamber, an anneal chamber, and combinations thereof.

25. The substrate processing system of claim 23, wherein the first conductive material comprises a columnar metal layer with a three dimensional metal porous dendritic structure deposited over the columnar metal layer.
